(19) United States
(12) Patent Application Publication
(10) Pub. No.: US 2011/0073363 A1
(43) Pub. Date: Mar. 31, 2011

(54) CIRCUIT MODULE AND ELECTRIC VEHICLE INCLUDING THE SAME

(75) Inventors: Takeshi NAGAO, Hirakata-City (JP); Hiroshi TAKAO, Hirakata-City (JP)

(73) Assignee: SANYO ELECTRIC CO., LTD., Moriguchi City (JP)

(21) Appl. No.: 12/889,685

(22) Filed: Sep. 24, 2010

(30) Foreign Application Priority Data
Sep. 30, 2009 (JP) 2009-227917
Aug. 24, 2010 (JP) 2010-187034

(51) Int. Cl. H05K 5/00

(52) U.S. Cl. 174/549

(57) ABSTRACT

A circuit board is accommodated in an internal space of a main body casing, and a bus bar electrically connected to the circuit board is drawn out of the main body casing. The bus bar is held in an internal region of a terminal holder positioned outside the main body casing. One end of a harness is connected to the bus bar in the internal region of the terminal holder, and the other end of the harness is drawn out to an external space. In this state, a joint region of a terminal cover is joined to a joint region of the terminal holder.

### BACKGROUND OF THE INVENTION

1. Field of the Invention

The present invention relates to a circuit module and an electric vehicle including the same.

2. Description of the Background Art

Examples of an electric vehicle include a two-wheeled electric vehicle provided with a battery system, a power converter, a motor and a drive wheel. During traveling of the two-wheeled electric vehicle, the power converter converts electric power supplied from the battery system into electric power (driving power) required for driving the drive wheel.

The power converter includes electronic circuits such as an inverter circuit. Therefore, in the case of providing the power converter in the two-wheeled electric vehicle that is used outdoors, liquid such as rainwater must be reliably prevented from coming in contact with the electronic circuits of the power converter and connections between the electronic circuits and wires.

JP 9-199871 A discloses an example of waterproof construction of an electronic device. In the electronic device having the waterproof construction of JP 9-199871 A, a lower case and an upper case are joined through a waterproof rubber gasket, thereby forming a main body that accommodates a substrate. A hole for passing a harness therethrough is formed in part of the waterproof rubber gasket. The harnesses are passed through the holes of the waterproof rubber gasket, and one end of the harness is soldered to the substrate inside the main body.

Applying the waterproof construction of the electronic device disclosed in JP 9-199871 A is considered in order to ensure waterproofness of the power converter of the two-wheeled electric vehicle and the connections between the power converter and the wires.

However, applying the waterproof construction of JP 9-199871 A to the power converter makes it difficult to replace the wires.

### BRIEF SUMMARY OF THE INVENTION

An object of the present invention is to provide a circuit module which can be reliably waterproofed and in which wires can be easily replaced, and an electric vehicle including the same.

(1) According to an aspect of the present invention, a circuit module includes a first casing having an internal space, an electronic circuit accommodated in the internal space of the first casing, a terminal electrically connected to the electronic circuit and drawn out of the first casing, a terminal holder provided outside the first casing, having an internal region in which the terminal is held, and having a first joint region that surrounds the internal region, a wire, and a cover having a second joint region that corresponds to the first joint region of the terminal holder, and formed to cover the internal region of the terminal holder, wherein the second joint region of the cover is joined to the first joint region of the terminal holder while one end of the wire is connected to the terminal in the internal region of the terminal holder and the other end of the wire is drawn out to an external space.

In the circuit module, the electronic circuit is accommodated in the internal space of the first casing, and the terminal electrically connected to the electronic circuit is drawn out of the first casing. The terminal is held in the internal region of the terminal holder provided outside the first casing. The terminal holder has the first joint region that surrounds the internal region. The cover has the second joint region corresponding to the first joint region of the terminal holder. The one end of the wire is connected to the terminal in the internal region of the terminal holder while the other end of the wire is drawn out to the external space. In this state, the second joint region of the cover is joined to the first joint region of the terminal holder.

In this manner, the waterproofness of the electronic circuit is ensured by the first casing. A connection between the terminal and the wire is closed by the terminal holder and the cover. This ensures waterproofness of the connection between the terminal and the wire. In this case, removing the wire from the terminal allows the wire to be easily removed from the terminal holder without disassembling the first casing. As a result, the circuit module can be reliably waterproofed and the wire is easily replaced.

(2) The circuit module may further include a seal member arranged on the first joint region to surround the internal region of the terminal holder, and having a plurality of holes that pass the seal member from the external space to the internal region, wherein the terminal may include a plurality of terminals, and the wire may include a plurality of wires, the plurality of wires can be inserted through the plurality of holes, respectively, of the seal member, the plurality of terminals may be held in the internal region of the terminal holder, the wires inserted through the plurality of holes of the seal member may be connected to the plurality of terminals, respectively, in the internal region of the terminal holder, and the second joint region of the cover may be joined to the first joint region of the terminal holder through the seal member.

In this case, the seal member is arranged on the first joint region to surround the internal region of the terminal holder, and has the plurality of holes that pass the seal member from the external space to the internal region. The plurality of wires are inserted through the plurality of holes, respectively, of the seal member, and connected to the plurality of terminals, respectively, held in the internal region of the terminal holder. In this state, the second joint region of the cover is joined to the first joint region of the terminal holder through the seal member.

Accordingly, the internal region including connections between the terminals and the wires are closed by the terminal holder, the cover and the seal member. This improves the waterproofness of the connections between the terminals and the wires.

The plurality of wires are integrated with the seal member. This causes the plurality of wires to be easily handled, and prevents erroneous connections between the plurality of wires and the plurality of terminals.

(3) The seal member may include a plurality of seal members, the first joint region may include a plurality of first joint regions, the second joint region may include a plurality of second joint regions, the terminal holder may have a plurality of internal regions in which the plurality of terminals are held, and the plurality of first joint regions that surround the plurality of internal regions, respectively, the cover may have the plurality of second joint regions that correspond to the plurality of first joint regions of the terminal holder, and the plurality of wires inserted through the plurality of holes of the plurality of seal members, respectively, may be connected to the plurality of terminals in the plurality of internal regions of the terminal holder, respectively, and the plurality of second joint regions of the cover may be joined to the plurality of first joint regions of the terminal holder through the plurality of seal members.

In this case, the plurality of wires are inserted through the holes of the plurality of seal members, respectively, and connected to the plurality of terminals held in the plurality of internal regions of the terminal holder, respectively. In this state, the plurality of second joint regions of the cover are joined to the plurality of first joint regions of the terminal holder through the plurality of seal members, respectively.

Accordingly, the plurality of wires and the plurality of terminals are independently integrated, respectively, through the plurality of seal members, and the internal regions including the respective connections between the wires and the terminals are closed by the common terminal holder and the common cover. As a result, the wires and the seal members can be integrally handled, respectively, and the respective connections between the plurality of wires and the plurality of terminals can be closed by the common terminal holder and the common cover, so that the plurality of wires can be reliably attached and removed in the smaller number of operation steps.

(4) The terminal holder may be formed such that the seal member can be fitted in the terminal holder, and the seal member may have a first surface and a second surface, and may be shaped so as to be fitted in the terminal holder while the first surface is opposite to the first joint region, and may be shaped so as not to be fitted in the terminal holder while the second surface is opposite to the first joint region.

In this case, although the seal member can be fitted in the terminal holder while the first surface is opposite to the first joint region of the terminal holder, the seal member cannot be fitted in the terminal holder while the second surface is opposite to the first joint region of the terminal holder.

Therefore, the seal member is prevented from being directed opposite to the normal direction between the terminal holder and the cover. Accordingly, the seal member can be easily and accurately attached.

(5) The first casing may have electrical conductivity, the terminal may be electrically insulated from the first casing, the wire may have a core and a shield conductor, the core may be connected to the terminal, and the shield conductor may be electrically connected to the first casing.

In this case, the core of the wire is connected to the terminal that is electrically insulated from the first casing. The shielded conductor of the wire is electrically connected to the first casing having electrical conductivity. Thus, the first casing functions as a shield of the electronic circuit. This allows the electronic circuit to be shielded with simple configuration and operation.

(6) The terminal may include a plurality of terminals, and the wire may include a plurality of wires, the terminal holder may have a plurality of grooves that are provided corresponding to the plurality of wires and cause the internal region and the external space to communicate with each other, the circuit module may further include a plurality of seal members that are formed so as to be fitted in the plurality of grooves of the terminal holder, respectively, and each have a hole that passes the seal member from the external space to the internal region, and the plurality of wires can be inserted through the holes of the plurality of seal members, respectively, the plurality of terminals are held in the internal region of the terminal holder, the plurality of wires inserted through the holes of the plurality of seal members may be connected to the plurality of terminals in the internal region of the terminal holder, and the second joint region of the cover may be joined to the first joint region of the terminal holder through the plurality of seal members.

In this case, the plurality of seal members are fitted in the plurality of grooves that cause the internal region of the terminal holder and the external space to communicate with each other. The plurality of wires are inserted through the holes of the plurality of seal members, and connected to the plurality of terminals in the internal region of the terminal holder, respectively. In this state, the second joint region of the cover is joined to the first joint region of the terminal holder.

Accordingly, portions between the plurality of grooves of the terminal holder and the plurality of seal members are sealed, and a portion between the first joint region of the terminal holder and the second joint region of the cover is sealed. Therefore, the internal region including connections between the terminals and the wires is closed by the terminal holder, the cover and the seal member. This results in improved waterproofness of the connections between the terminals and the wires.

The plurality of seal members and the plurality of grooves are provided corresponding to the plurality of wires. This allows the wires to be separately removed from the terminals. Thus, replacement operation of the wires can be efficiently performed.

(7) The circuit module may further include a second casing provided outside the first casing, wherein the terminals, the terminal holder and the cover may be accommodated in the second casing, and the plurality of wires may be drawn out from the second casing to the external space, and the first casing and the second casing may have electrical conductivity.

In this case, the electronic circuit is accommodated in the first casing having electrical conductivity, and the terminals are accommodated in the second casing having electrical conductivity. Thus, the electronic circuit and the terminals are shielded. As a result, entry of noise from the external space into the electronic circuit and the terminals can be suppressed, and emission of noise from the electronic circuit and the terminals to the external space can be suppressed.

(8) According to another aspect of the present invention, an electric vehicle includes a power converter composed of the circuit module according to the one aspect of the present invention, a battery system arranged to supply electric power to the power converter, a motor driven by the power converter, and a drive wheel rotated by a torque generated by the motor.

In the electric vehicle, the electric power is supplied from the battery system to the power converter. The electric power converted by the power converter is applied to the motor, thereby rotating the motor. The torque generated by the motor causes the drive wheel to rotate, so that the electric vehicle moves.

The power converter is constituted by the circuit module according to the one aspect of the present invention. Therefore, waterproofness of the power converter is ensured by the first casing even when the electric vehicle is used in wet weather or on a flooded road. The internal region including the connection between the terminal electrically connected to the power converter and the wire is closed by the terminal holder and the cover. Thus, waterproofness of the connection between the terminal and the wire is ensured. In this case, removing the wire from the terminal allows the wire to be easily removed from the terminal holder without disassembling the first casing. As a result, the circuit module can be reliably waterproofed and the wire can be easily replaced.

According to the present invention, the circuit module can be reliably waterproofed, and the wire can be easily replaced.

Other features, elements, characteristics, and advantages of the present invention will become more apparent from the following description of preferred embodiments of the present invention with reference to the attached drawings.

### BRIEF DESCRIPTION OF THE SEVERAL VIEWS OF THE DRAWINGS

FIG. 1 is a side view of a two-wheeled electric vehicle according to a first embodiment of the present invention;

FIG. 2 is a block diagram for explaining a control system of the two-wheeled electric vehicle of FIG. 1;

FIG. 3 is an external perspective view of a power converter constituted by a circuit module according to the first embodiment of the present invention;

FIG. 4 is a plan view of the power converter of FIG. 3;

FIG. 5 is an exploded perspective view of the power converter of FIGS. 3 and 4;

FIG. 6 is an exploded perspective view of the power converter of FIGS. 3 and 4;

FIG. 7 is a perspective view and a plan view of a terminal holder of FIG. 5;

FIG. 8 is a perspective view of a rubber gasket to which a motor power line group is attached;

FIG. 9 is a perspective view of a rubber gasket to which an electric power line group is attached;

FIG. 10 is a bottom view of a terminal cover;

FIG. 11 is a bottom view of a terminal cover;

FIG. 12 is a vertical sectional view taken along the line A-A of FIG. 4;

FIG. 13 is a plan view showing another example of the terminal holder;

FIG. 14 is a plan view showing another example of the rubber gaskets;

FIG. 15 is a plan view showing another example of the terminal covers;

FIG. 16 is a plan view showing still another example of the terminal holder;

FIG. 17 is a plan view showing still another example of the rubber gaskets;

FIG. 18 is an exploded perspective view showing another example of a wire connector;

FIG. 19 is a bottom view of a terminal cover in the wire connector of FIG. 18;

FIG. 20 is an external perspective view of a power converter constituted by a circuit module according to a second embodiment of the present invention;

FIG. 21 is an exploded perspective view of the power converter of FIG. 20;

FIG. 22 is an exploded perspective view of the power converter of FIG. 20;

FIG. 23 is a perspective view and a plan view of a terminal holder of FIG. 21;

FIG. 24 is a bottom view of a top cover;

FIG. 25 is a perspective view showing another example of the top cover of a connection casing; and

FIG. 26 is a perspective view showing still another example of the top cover of the connection casing.

### DETAILED DESCRIPTION OF THE INVENTION

### [1] First Embodiment

(1) Two-Wheeled Electric Vehicle

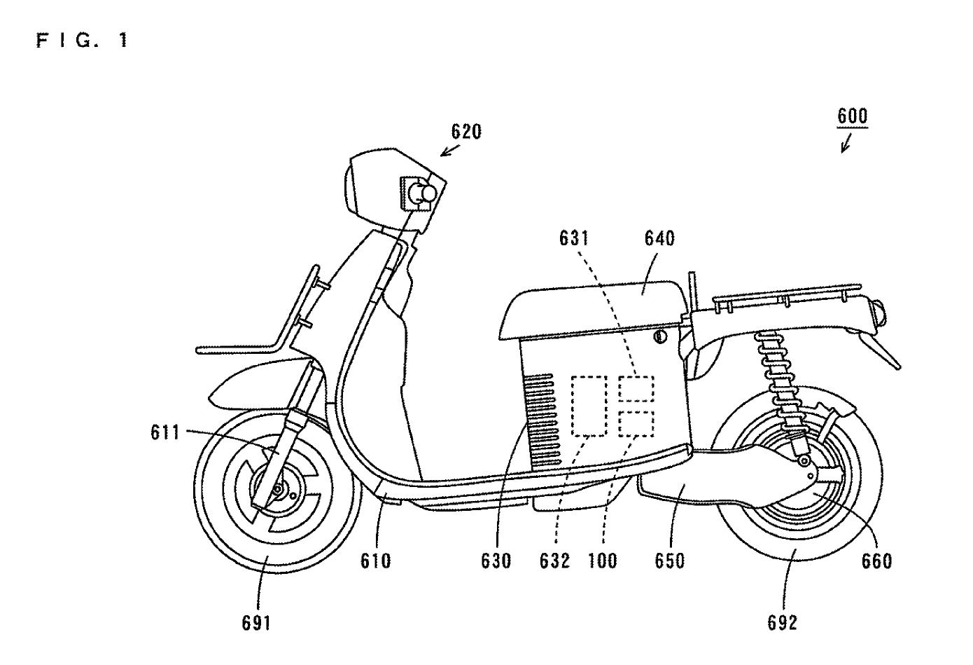

Description will be made of a circuit module and an electric vehicle including the same according to a first embodiment of the present invention while referring to the drawings. In the following paragraphs, a two-wheeled electric vehicle is described as an example of the electric vehicle. FIG. 1 is a side view of the two-wheeled electric vehicle according to the first embodiment of the present invention. As shown in FIG. 1, the two-wheeled electric vehicle 600 according to the present embodiment includes a vehicle body frame 610, a front fork 611, a handle 620, a main body 630, a seat 640, a swing arm 650, a motor 660, a front wheel 691 and a rear wheel 692. In the following description, front, rear, left and right means front, rear, left and right directions seen from a position of a driver seated on the seat 640 of the two-wheeled electric vehicle 600.

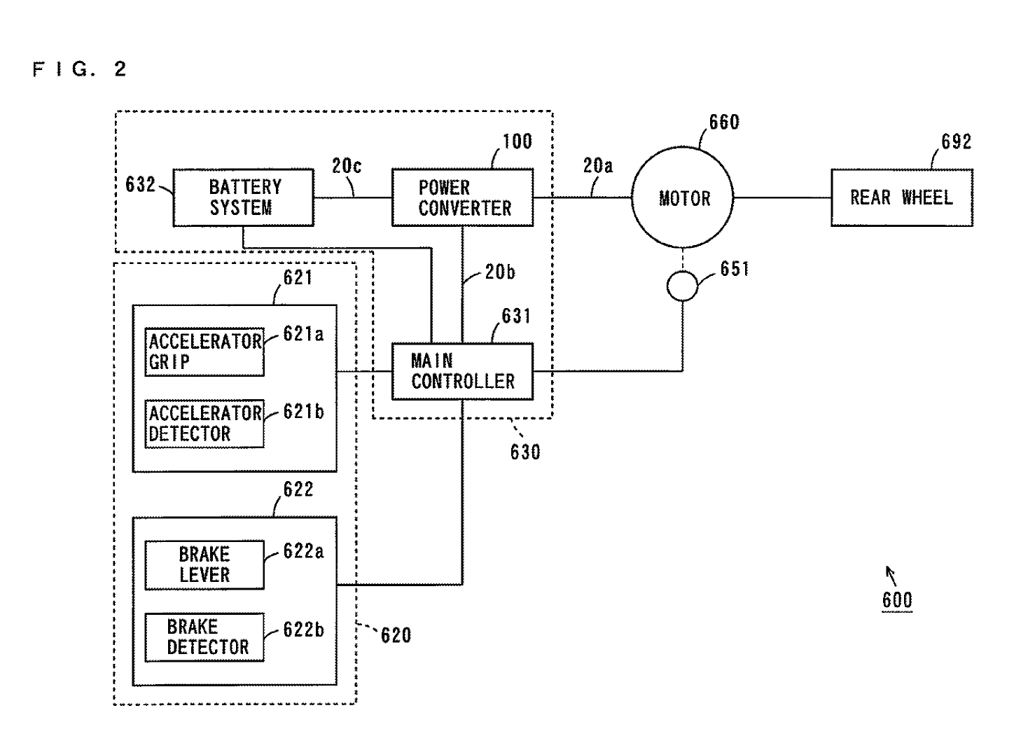

The vehicle body frame 610 is of an underbone type, and provided to extend in a front-to-rear direction in a lower portion of the two-wheeled electric vehicle 600. The front fork 611 is attached to a front end portion of the vehicle body frame 610 so as to swing from side to side. The front wheel 691 is attached to a lower end portion of the front fork 611. The handle 620 is attached to an upper end portion of the front fork 611. The handle 620 includes an accelerator 621 (FIG. 2, described below) and a brake 622 (FIG. 2, described below). Details will be described in the following paragraphs.

The main body 630 is attached to a portion from the center to the rear of the vehicle body frame 610. A power converter 100, a main controller 631 and a battery system 632 are provided in the main body 630. The power converter 100 is constituted by the circuit module according to the present embodiment. Details of the power converter 100, the main controller 631 and the battery system 632 will be described below. The seat 640 is provided in an upper end portion of the main body 630.

The swing arm 650 is attached to a rear end portion of the vehicle body frame 610 to extend in the rear direction. In this state, a rear end portion of the swing arm 650 can swing in an up-and-down direction with respect to the vehicle body frame 610. The motor 660 is provided at a rear end of the swing arm 650. The rear wheel 692 is attached to a rotation shaft of the motor 660. Thus, a torque generated by the motor 660 is transmitted to the rear wheel 692 through the rotation shaft during operation of the motor 660.

Next, a control system of the two-wheeled electric vehicle 600 of FIG. 1 is described. FIG. 2 is a block diagram for explaining the control system of the two-wheeled electric vehicle 600 of FIG. 1.

As shown in FIG. 2, the two-wheeled electric vehicle 600 includes the power converter 100, the main controller 631, the battery system 632, the accelerator 621, the brake 622, a rotation speed sensor 651 and the motor 660 as components of the control system that adjusts the torque of the rear wheel 692.

Here, the accelerator 621 includes an accelerator grip 621a and an accelerator detector 621b, and the brake 622 includes a brake lever 622a and a brake detector 622b. The rotation speed sensor 651 is incorporated in the motor 660 of FIG. 1. The motor 660 incorporates a decelerator in the present embodiment.

The battery system 632 includes a plurality of battery modules and a battery ECU (Electronic Control Unit). The plurality of battery modules of the battery system 632 are connected to the motor 660 through the power converter 100.

The battery ECU of the battery system 632 is connected to the main controller 631. This causes an amount of charge of the plurality of battery modules to be applied from the battery ECU to the main controller 631.

The accelerator 621, the brake 622 and the rotation speed sensor 651 are connected to the main controller 631. The main controller 631 is composed of a CPU (Central Processing Unit) and a memory, or composed of a microcomputer, for example.

When the driver operates the accelerator grip 621a, the accelerator detector 621b detects an operation amount of the accelerator grip 621a with reference to an unoperated state. The detected operation amount of the accelerator grip 621a is applied to the main controller 631.

When the brake lever 622a is operated by the driver, the brake detector 622b detects an operation amount of the brake lever 622a with reference to an unoperated state. The detected operation amount of the brake lever 622a is applied to the main controller 631.

The rotation speed sensor 651 detects the rotation speed of the motor 660. The detected rotation speed is applied to the main controller 631.

In this manner, information including the amount of charge of the battery modules, the operation amount of the accelerator grip 621a, the operation amount of the brake lever 622a, the rotation speed of the motor 660 and so on is applied to the main controller 631. The main controller 631 performs charge/discharge control of the battery modules and power conversion control of the power converter 100 based on the information.

Electric power generated by the battery modules is supplied from the battery system 632 to the power converter 100 at the time of starting and accelerating the two-wheeled electric vehicle 600 based on the accelerator operation, for example.

Furthermore, the main controller 631 calculates a torque to be transmitted to the rear wheel 692 as a commanded torque based on the given operation amount of the accelerator grip 621a, and applies a control signal based on the commanded torque to the power converter 100.

The power converter 100 converts the electric power supplied from the battery system 632 into electric power (driving power) required for driving the rear wheel 692 based on the control signal given from the main controller 631. Accordingly, the driving power converted by the power converter 100 is supplied to the motor 660, and the torque of the motor 660 based on the driving power is transmitted to the rear wheel 692.

Meanwhile, the motor 660 functions as a power generation system at the time of decelerating the two-wheeled electric vehicle 600 based on the brake operation. In this case, the power converter 100 converts regenerated electric power generated by the motor 660 to electric power suitable for charging the battery modules, and supplies the electric power to the battery module. This causes the battery modules to be charged.

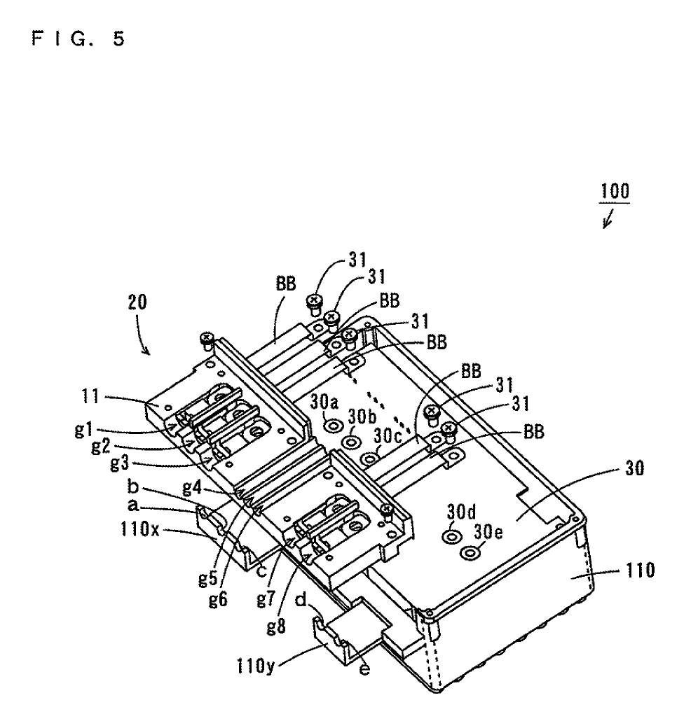

Here, the power converter 100 includes a circuit board 30 (FIG. 5, described below) in the two-wheeled electric vehicle 600 according to the present embodiment. The power converter 100 also includes a signal line group 20b for connecting the circuit board 30 (FIG. 5, described below) and the main controller 631. The power converter 100 also includes an electric power line group 20c for connecting the circuit board 30 (FIG. 5, described below) and the battery system 632. Furthermore, the power converter 100 includes a motor power line group 20a for connecting the circuit board 30 (FIG. 5, described below) and the motor 660. Each of the signal line group 20b, the electric power line group 20c and the motor power line group 20a is constituted by a plurality of harnesses.

Hereinafter, description is made of details of the power converter 100.

(2) Configuration of the Power Converter

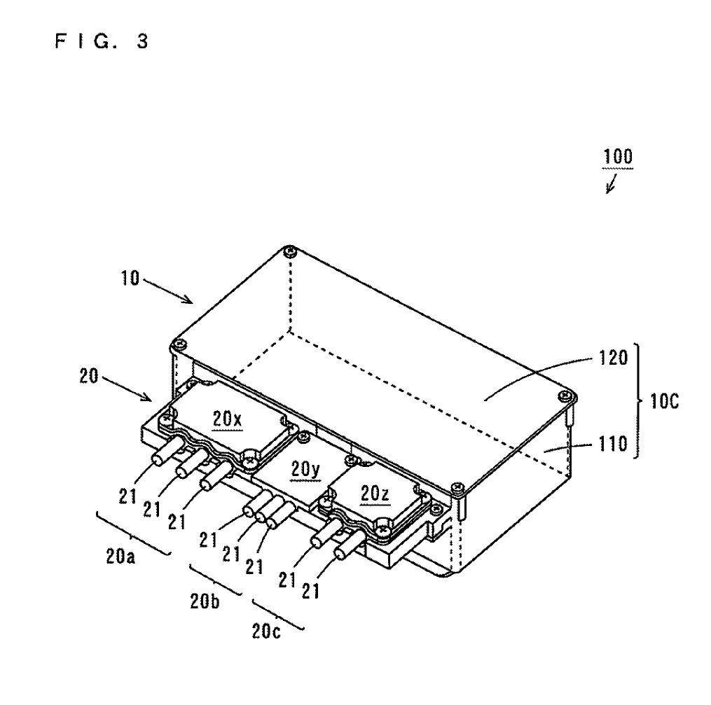

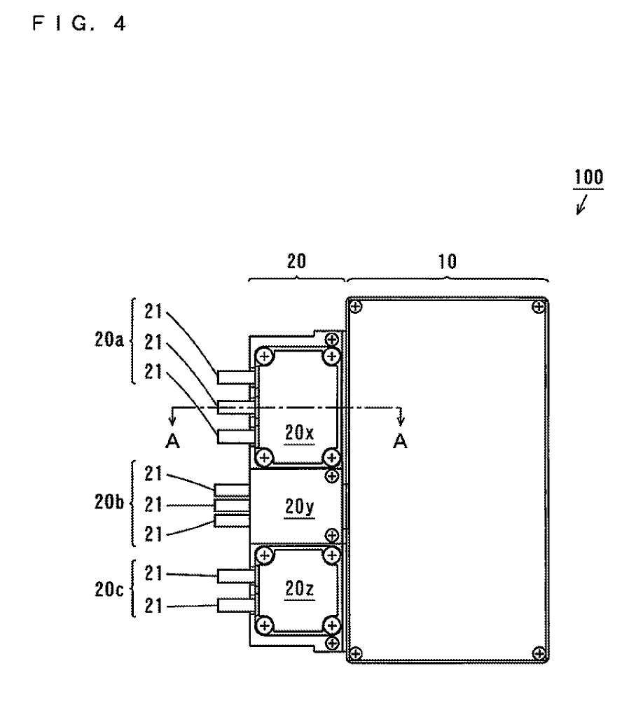

FIG. 3 is an external perspective view of the power converter 100 constituted by the circuit module according to the first embodiment of the present invention. FIG. 4 is a plan view of the power converter 100 of FIG. 3.

As shown in FIGS. 3 and 4, the power converter 100 is constituted by a converter main body 10 and a wire connector 20.

The circuit board 30 (FIG. 5), described below, is accommodated in a box-shaped main body casing 10C in the converter main body 10. The main body casing 10C is composed of a lower casing 110 having an upper opening, and a top cover 120 that closes the upper opening of the lower casing 110. The main body casing 10C is formed of an electrically conductive material such as aluminum.

The lower casing 110 has four side surfaces and a bottom surface. A wire connector 20 is integrally formed with the lower casing 110 to extend sideward from one side surface.

In the present embodiment, the wire connector 20 includes a first connector portion 20x, a second connector portion 20y and a third connector portion 20z. One ends of the motor power line group 20a, the signal line group 20b and the electric power line group 20c of FIG. 3 are connected to the first connector portion 20x, the second connector portion 20y and the third connector portion 20z, respectively. The first connector portion 20x and the third connector portion 20z have waterproof construction.

The motor power line group 20a and the signal line group 20b are each constituted by the three harnesses 21, and the electric power line group 20c is constituted by the two harnesses 21.

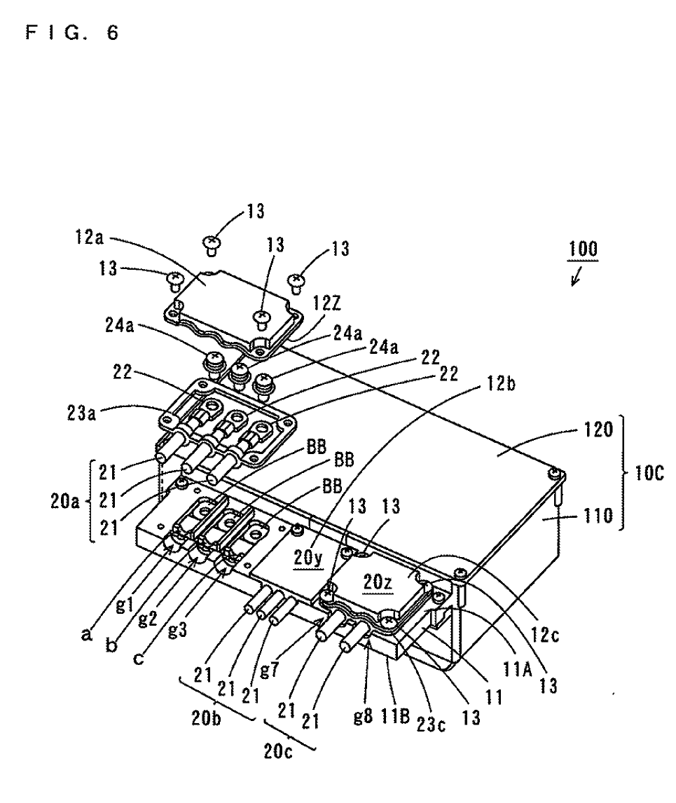

FIGS. 5 and 6 are exploded perspective views of the power converter 100 of FIGS. 3 and 4.

Electronic circuits such as an inverter circuit for driving the motor 660 of FIG. 2 are mounted on the circuit board 30. The circuit board 30 is accommodated within the lower casing 110.

As shown in FIG. 5, three terminals 30a, 30b, 30c corresponding to the motor power line group 20a of FIG. 3 are formed on an upper surface of the circuit board 30. Two terminals 30d, 30e corresponding to the electric power line group 20c of FIG. 3 are formed on the upper surface of the circuit board 30. Each of the terminals 30a to 30e has a screw hole for connecting a strip-shaped bus bar BB thereto. Three terminals (not shown) corresponding to the signal line group 20b of FIG. 3 are also formed on the circuit board 30.

The wire connector 20 is constituted by two supports 110x, 110y shown in FIG. 5, a terminal holder 11 shown in FIG. 5, rubber gaskets 23a, 23c shown in FIG. 6 and terminal covers 12a, 12b, 12c shown in FIG. 6.

As shown in FIG. 5, the two supports 110x, 110y are integrally formed with a distance therebetween on the one side surface of the lower casing 110. Each of the two supports 110x, 110y has a constant width, and extends in a horizontal direction. A tip portion of each of the two supports 110x, 110y is bent upward.

Three concave portions a, b, c, each of which has a semicircular shape in cross section, corresponding to the motor power line group 20a of FIG. 3 are formed at an upper end of the tip portion of the support 110x. Two concave portions d, e, each of which has a semicircular shape in cross section, corresponding to the electric power line group 20c of FIG. 3 are formed at an upper end of the tip portion of the support 110y. The terminal holder 11 made of resin is mounted on the two supports 110x, 110y.

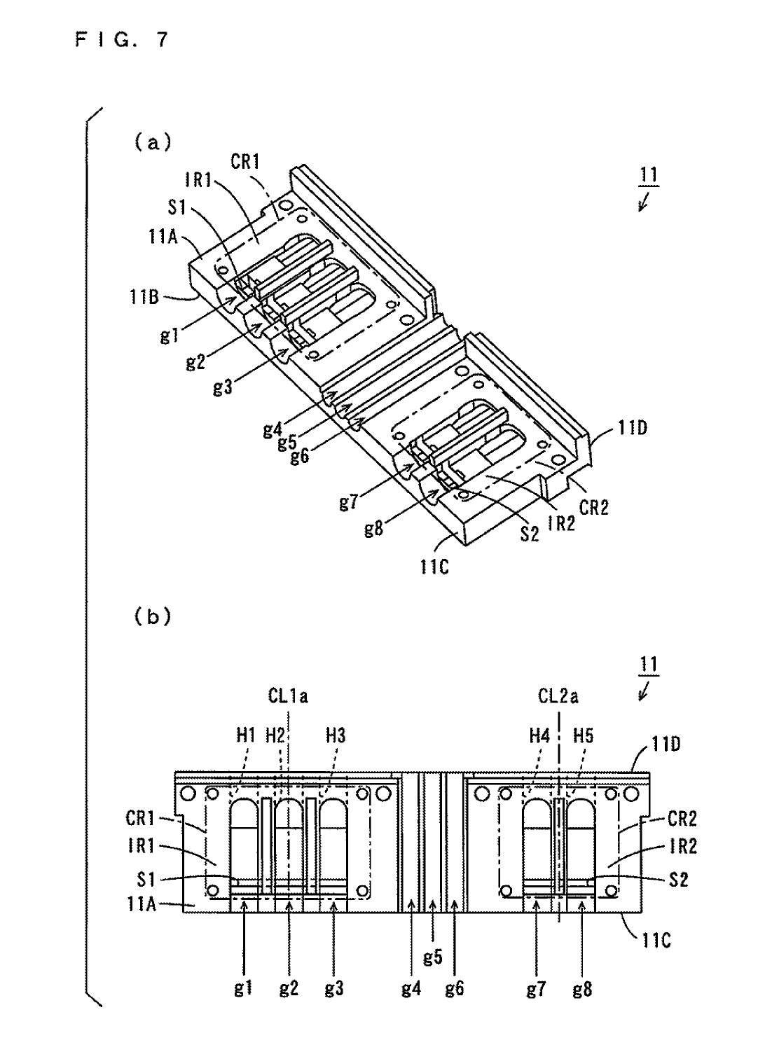

FIG. 7 (a) is a perspective view of the terminal holder 11 of FIG. 5, and FIG. 7 (b) is a plan view of the terminal holder 11 of FIG. 5.

As shown in FIG. 7 (a), the terminal holder 11 is made of a plate-like member having a rectangular shape, and has an upper surface 11A, a lower surface 11B, one end surface 11C and the other end surface 11D.

A plurality of concave grooves g1, g2, g3, g7, g8 are formed parallel to one another on the upper surface 11A of the terminal holder 11 to extend from the one end surface 11C to portions near the other end surface 110. A plurality of concave grooves g4, g5, g6 are formed parallel to one another between the concave grooves g1, g2, g3 and the concave grooves g7, g8 to extend from the one end surface 11C to the other end surface 11D.

The three concave grooves g1, g2, g3 correspond to the motor power line group 20a of FIG. 3, and formed in the first connector portion 20x of FIG. 3. The three concave grooves g4, g5, g6 correspond to the signal line group 20b of FIG. 3, and formed in the second connector portion 20y. The two concave grooves g7, g8 correspond to the electric power line group 20c of FIG. 3, and formed in the third connector portion 20z. A tip portion of each of the concave grooves g1, g2, g3, g7, g8 is formed to have a semicircular shape in cross section. An entire portion of each of the concave grooves g4, g5, g6 is formed to have a semicircular shape in cross section.

A joint region CR1 is formed on the upper surface 11A to surround the three concave grooves g1, g2, g3 in an integrated manner excluding the tip portions of the concave grooves g1, g2, g3. A joint region CR2 is formed on the upper surface 11A to surround the two concave grooves g7, g8 in an integrated manner excluding the tip portions of the concave grooves g7, g8. A region inside the joint region CR1 is referred to as an internal region IR1, and a region inside the joint region CR2 is referred to as an internal region IR2.

The concave grooves g1, g2, g3 are symmetrically arranged with respect to a center line CL1a of the internal region IR1 in this example. Here, the center line CL1a is a straight line passing through the center of two sides of the internal region IR1 that are parallel to the one end surface 11C. The concave grooves g7, g8 are symmetrically arranged with respect to a center line CL2a of the internal region IR2. Here, the center line CL2a is a straight line passing through the center of two sides of the internal region IR2 that are parallel to the one end surface 11C.

As shown in FIG. 7 (b), a slit S1 parallel to the one end surface 11C is formed to vertically penetrate the terminal holder 11 from the lower surface 11B to the internal region 1R1. A slit S2 parallel to the one end surface 11C is formed to vertically penetrate the terminal holder 11 from the lower surface 11B to the internal region IR2.

The tip portion of the support 110x of FIG. 5 is inserted from the lower surface 11B into the slit S1, and the tip portion of the support 110y of FIG. 5 is inserted from the lower surface 11B into the slit 82. In this state, upper surfaces of the three concave portions a, b, c of the support 110x are substantially flush with upper surfaces of the three concave grooves g1, g2, g3 of the terminal holder 11. Upper surfaces of the two concave portions d, e of the support 110y are substantially flush with upper surfaces of the two concave grooves g7, g8 of the terminal holder 11 (see FIG. 6).

As shown in FIG. 7 (b), a plurality of slits H1, H2, H3, H4, H5 that are parallel to the lower surface 11B and extend from the other end surface 110 into the concave grooves g1, g2, g3, g7, g8, respectively, are formed in the terminal holder 11.

The foregoing strip-shaped bus bar BB is inserted in each of the plurality of slits H1, H2, H3, H4, H5 (see FIG. 5). One ends of the plurality of bus bars BB are exposed inside the concave grooves g1, g2, g3, g7, g8. Each of the plurality of bus bars BB is formed of copper, for example, and has connection holes at its both ends.

As described above, the tip portions of the supports 110x, 110y of the lower casing 110 are inserted in the slits S1, S2 of the terminal holder 11. This causes the terminal holder 11 to be fixed to the lower casing 110 as shown in FIG. 5. The connection holes at one ends of the plurality of bus bars BB are positioned in the concave grooves g1, g2, g3, g7, g8 of the terminal holder 11, and the connection holes at the other ends of the plurality of bus bars BB are positioned on the plurality of terminals 30a, 30b, 30c, 30d, 30e of the circuit board 30.

In this state, the other ends of the plurality of bus bars BB are connected to the screw holes of the plurality of terminals 30a, 30b, 30c, 30d, 30e of the circuit board 30 by screws 31 through the connection holes.

The three harnesses 21 constituting the signal line group 20b are fitted in the three concave grooves g4, g5, g6 of the terminal holder 11, respectively, and ends of the three harnesses 21 are electrically connected to the circuit board 30. Concave grooves each having a semicircular shape and being opposite to the three concave grooves g4, g5, g6 of the terminal holder 11 are formed on a lower surface of the terminal cover 12b. The terminal cover 12b is formed of resin. The terminal cover 12b is mounted on the terminal holder 11 to cover the harnesses 21 in the concave grooves g4, g5, g6 of the terminal holder 11.

In this state, an internal space of the lower casing 110 is filled with resin, and the top cover 120 is attached to the lower casing 110.

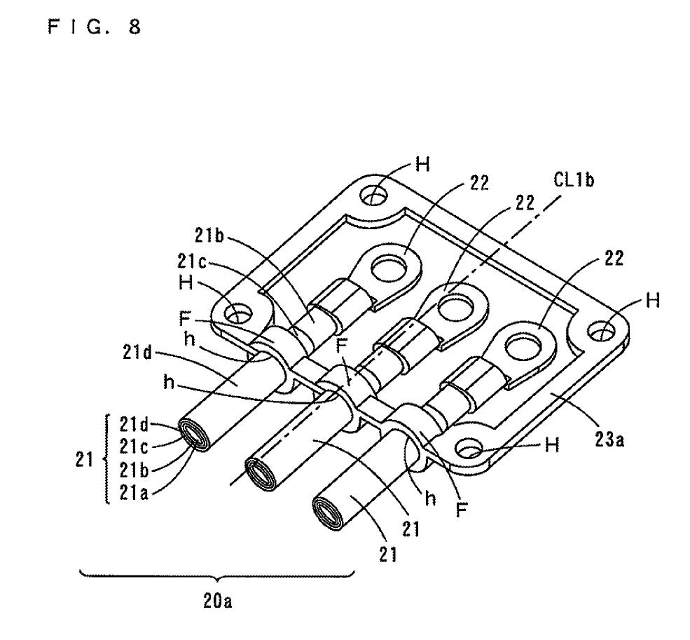

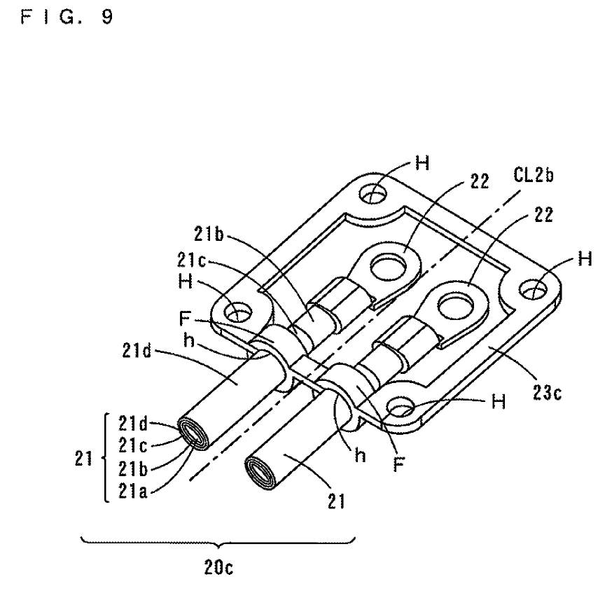

FIG. 8 is a perspective view of the rubber gasket 23a to which the motor power line group 20a is attached. FIG. 9 is a perspective view of the rubber gasket 23c to which the electric power line group 20c is attached.

As shown in FIG. 8, the rubber gasket 23a has a rectangular shape corresponding to the joint region CR1 of the upper surface 11A of the terminal holder 11. The rubber gasket 23a surrounds the internal region IR1 while being arranged on the joint region CR1 of the upper surface 11A of the terminal holder 11.

Three cylindrical attachment portions F each having a through hole h that penetrates the rubber gasket 23a from the outside to the inside are integrally formed at a distance from one another at one side of the rubber gasket 23a. The inner diameter of each of the through holes h is substantially equal to the diameter of each harness 21 of the motor power line group 20a. Screw holes H are formed at four corners of the rubber gasket 23a.

The three through holes h and three attachment portions F are symmetrically arranged with respect to a center line CU b of the rubber gasket 23a in this example. Here, the center line CL1b is a straight line passing through the midpoint of the one side of the rubber gasket 23a at which the through holes h are formed and the midpoint of the other side being opposite thereto.

As shown in FIG. 9, the rubber gasket 23c has a rectangular shape corresponding to the joint region CR2 of the upper surface 11A of the terminal holder 11. The rubber gasket 23c surrounds the internal region 1R2 while being arranged on the joint region CR2 of the upper surface 11A of the terminal holder 11.

Two cylindrical attachment portions F each having a through hole h that penetrates the rubber gasket 23c from the outside to the inside are integrally formed at a distance from each other at one side of the rubber gasket 23c. The inner diameter of each of the through holes h is substantially equal to the diameter of the harness 21 of the electric power line group 20c. Screw holes H are formed at four corners of the rubber gasket 23c.

The two through holes h and two attachment portions F are symmetrically arranged with respect to a center line CL2b of the rubber gasket 23c in this example. Here, the center line CL2b is a straight line passing through the midpoint of the one side of the rubber gasket 23c at which the through holes h are formed and the midpoint of the other side being opposite thereto.

Each of the harnesses 21 constituting the motor power line group 20a of FIG. 8 and the electric power line group 20c of FIG. 9 is a coaxial cable composed of a core 21a, insulating films 21b, 21d and a shield line 21c. An outer periphery of the core 21a is covered with the insulating film 21b, the shield line 21c and the insulating film 21d, A solderless terminal 22 is attached to the core 21a exposed at a tip portion of each harness 21.

The three harnesses 21 of FIG. 8 are inserted through the through holes h of the rubber gasket 23a, respectively. The solderless terminal 22 attached to the tip portion of each harness 21 is positioned inside the rubber gasket 23a. The two harnesses 21 of FIG. 9 are inserted through the through holes h of the rubber gasket 23c. The solderless terminal 22 attached to the tip portion of each harness 21 is positioned inside the rubber gasket 23c.

As shown in FIG. 6, the rubber gasket 23a is arranged on the joint region CR1 of the upper surface 11A of the terminal holder 11, and the three attachment portions F are fitted in the three concave grooves g1, g2, g3 of the terminal holder 11, respectively, while the three harnesses 21 constituting the motor power line group 20a are inserted in the rubber gasket 23a.

In this state, the three solderless terminals 22 positioned inside the rubber gasket 23a are connected to the respective bus bars BB exposed in the three concave grooves g1, g2, 93 by screws 24a.

Similarly, the rubber gasket 23c is arranged on the joint region CR2 of the upper surface 11A of the terminal holder 11, and the two attachment portions F are fitted in the two concave grooves g7, g8 of the terminal holder 11, respectively, while the two harnesses 21 constituting the electric power line group 20c are inserted in the rubber gasket 23c.

In this state, the two solderless terminals 22 positioned inside the rubber gasket 23c are connected to the respective bus bars BB exposed in the two concave grooves g7, g8 by screws 24a.

The terminal cover 12a made of resin is attached to the joint region CR1 (FIG., 7 (a)) of the upper surface 11A of the terminal holder 11 with the rubber gasket 23a sandwiched therebetween.

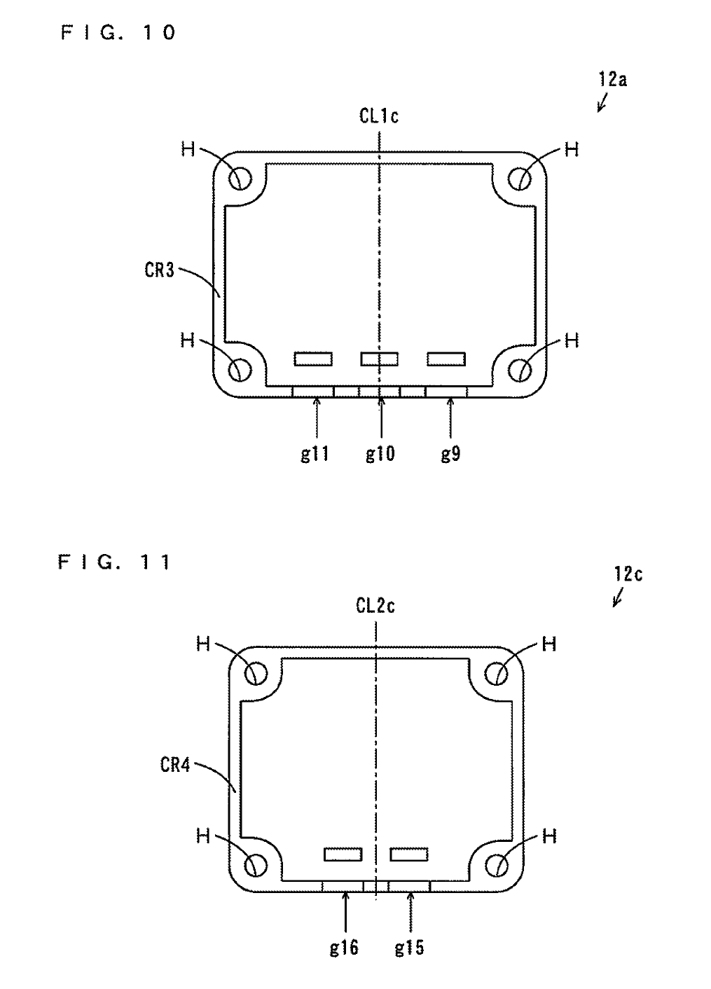

FIG. 10 is a bottom view of the terminal cover 12a. As shown in FIG. 10, a joint region CR3 is formed at a peripheral edge portion on a lower surface of the terminal cover 12a. The joint region CR3 has a rectangular shape corresponding to the joint region CR1 of the upper surface 11A of the terminal holder 11. The joint region CR3 projects downward as compared with a region inside thereof. Three concave grooves g9, g10, g11 each having a semicircular shape corresponding to the attachment portion F (see FIG. 8) of the rubber gasket 23a are formed at one side of the joint region CR3, Screw holes H are formed at four corners of the terminal cover 12a.

The concave grooves g9, g10, g11 are symmetrically arranged with respect to a center line CL1c of the joint region CR3 in this example. Here, the center line CL1c is a straight line passing through the midpoint of the one side of the joint region CR3 at which the concave grooves g9, g10, g11 are formed and the midpoint of the other side being opposite thereto.

The joint region CR3 of the terminal cover 12a is arranged on the rubber gasket 23a, and the concave grooves g9, g10, g11 are positioned on the three attachment portions F of the rubber gasket 23a, respectively. In this state, the terminal cover 12a is attached to the upper surface 11A of the terminal holder 11 by screws 13 (see FIG. 6) with the rubber gasket 23a sandwiched therebetween.

Accordingly, the terminal holder 11, the rubber gasket 23a and the terminal cover 12a form a closed space above the internal region IR1 of the terminal holder 11.

Similarly, the terminal cover 12c made of resin is attached to the joint region CR2 (FIG. 7 (a)) of the upper surface 11A of the terminal holder 11 with the rubber gasket 23c sandwiched therebetween.

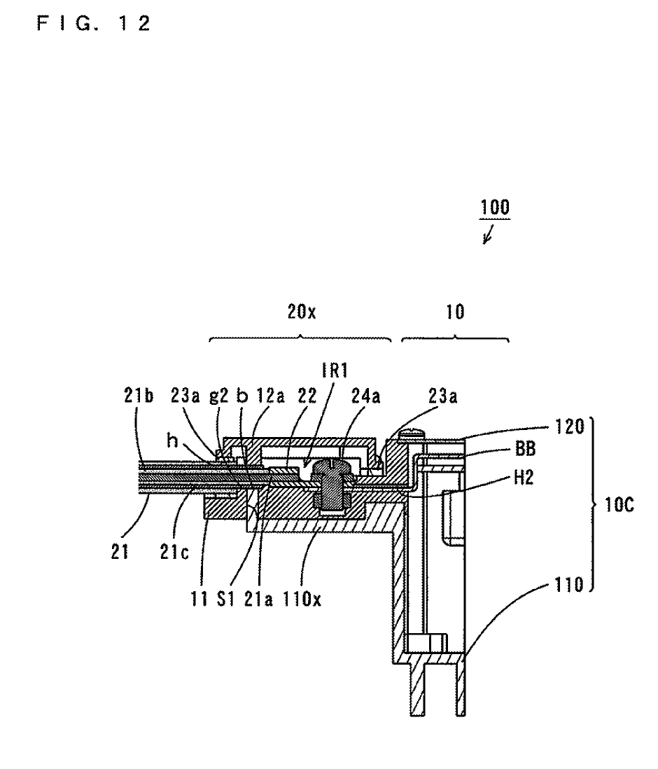

FIG. 11 is a bottom view of the terminal cover 12c. As shown in FIG. 11, a joint region CR4 is formed at a peripheral edge portion on a lower surface of the terminal cover 12c. The joint region CR4 has a rectangular shape corresponding to the joint region CR2 of the upper surface 11A of the terminal holder 11. The joint region CR4 projects downward as compared with a region inside thereof. Two concave grooves g15, g16 each having a semicircular shape corresponding to the attachment portion F (see FIG. 9) of the rubber gasket 23c are formed at one side of the joint region CR4. Screw holes H are formed at four corners of the terminal cover 12c.

The concave grooves g15, g16 are symmetrically arranged with respect to a center line CL2c of the joint region CR4 in this example. Here, the center line CL2c is a straight line passing through the midpoint of the one side of the joint region CR4 at which the concave grooves g15, g16 are formed and the midpoint of the other side being opposite thereto.

The joint region CR4 of the terminal cover 12c is arranged on the rubber gasket 23c, and the concave grooves g15, g16 are positioned on the two attachment portions F of the rubber gasket 23c, respectively. In this state, the terminal cover 12c is attached to the upper surface 11A of the terminal holder 11 by screws 13 (see FIG. 6) with the rubber gasket 23c sandwiched therebetween.

Accordingly, the terminal holder 11, the rubber gasket 23c and the terminal cover 12c form a closed space above the internal region IR2 of the terminal holder 11.

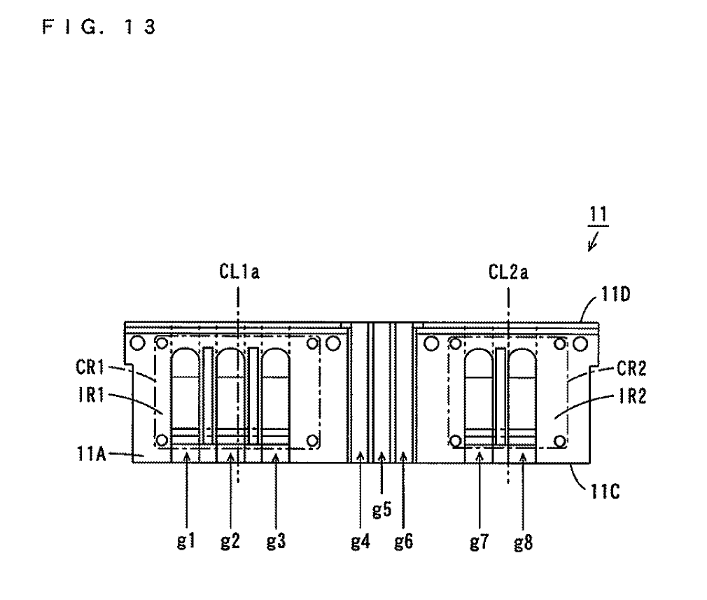

FIG. 12 is a vertical sectional view of the power converter 100 taken along the line A-A of FIG. 4. As shown in FIG. 12, the solderless terminal 22 attached to the harness 21 constituting the motor power line group 20a (FIG. 4) is connected to the bus bar BB in the closed space above the internal region IR1 of the terminal holder 11 in the first connector portion 20x. This causes the three harnesses 21 of the motor power line group 20a to be electrically connected to the three terminals 30a, 30b, 30c (FIG. 5) of the circuit board 30, respectively, through the bus bars BB.

The shield lines 21c of the three harnesses 21 are held while abutting against the concave portions a, b, c of the support 110x of the lower casing 110, respectively. Note that FIG. 12 only shows the concave portion b. This causes the shield lines 21c of the three harnesses 21 of the motor power line group 20a to be electrically connected to the lower casing 110.

As described above, the third connector portion 20z has substantially the same configuration as the first connector portion 20x. Therefore, also in the third connector portion 20z, the solderless terminal 22 attached to the harness 21 constituting the electric power line group 20c (FIG. 4) is connected to the bus bar BB in the closed space above the internal region IR2 of the terminal holder 11. This causes the two harnesses 21 of the electric power line group 20c to be electrically connected to the two terminals 30d, 30e (FIG. 5) of the circuit board 30, respectively, through the bus bars BB.

The shield lines 21c of the two harnesses 21 are held while abutting against the concave portions d, e of the support 110y of the lower casing 110, respectively. This causes the shield lines 21c of the two harnesses 21 of the electric power line group 20c to be electrically connected to the lower casing 110.

(3) Effects

(3-a) The Circuit Module

The circuit board 30 is accommodated in the internal space of the main body casing 10G. The inside of the main body casing 10C is filled with resin. This ensures waterproofness of the circuit board 30.

The internal region IR1 including the respective connections between the bus bars BB extending from the circuit board 30 and the three harnesses 21 of the motor power line group 20a is closed by the terminal holder 11, the terminal cover 12a and the rubber gasket 23a in the outside of the main body casing 10C. This ensures waterproofness of the internal region IR1 including the respective connections between the bus bars BB and the three harnesses 21 of the motor power line group 20a. In this case, the terminal cover 12a is removed from the terminal holder 11, and the rubber gasket 23a in which the harnesses 21 of the motor power line group 20a are inserted is removed from the terminal holder 11, so that the harnesses 21 of the motor power line group 20a can be easily removed without disassembling the main body casing 10G. As a result, the motor power line group 20a and the bus bars BB can be reliably waterproofed, and the motor power line group 20a can be easily replaced.

Similarly, the internal region IR2 including the respective connections between the bus bars 88 extending from the circuit board 30 and the two harnesses 21 of the electric power line group 20c is closed by the terminal holder 11, the terminal cover 12c and the rubber gasket 23c in the outside of the main body casing 10C. This ensures waterproofness of the internal region IR2 including the respective connections between the bus bars BB and the two harnesses 21 of the electric power line group 20c. In this case, the terminal cover 12c is removed from the terminal holder 11, and the rubber gasket 23c in which the harnesses 21 of the electric power line group 20c are inserted is removed from the terminal holder 11, so that the harnesses 21 of the electric power line group 20c can be easily removed without disassembling the main body casing 10C. As a result, the electric power line group 20c and the bus bars BB can be reliably waterproofed, and the electric power line group 20c can be easily replaced.

(3-b) Shielding of the Main Body Casing

The core 21a of the harness 21 is connected to the bus bar BB, which is electrically insulated from the main body casing 100, through the solderless terminal 22. The shield line 21c of the harness 21 is electrically connected to the main body casing 10C having electrical conductivity. Thus, the main body casing 10C functions as a shield of the circuit board 30. Accordingly, the circuit board 30 can be shielded with simple configuration and operation.

(3-c) The Motor Power Line and the Electric Power Line

The three harnesses 21 of the motor power line group 20a are inserted through the three through holes h of the rubber gasket 23a, respectively, thereby being integrated with the rubber gasket 23a. As a result, the three harnesses 21 of the motor power line group 20a are easily handled, and the three harnesses 21 of the motor power line group 20a are prevented from being improperly connected to the three bus bars BB.

The two harnesses 21 of the electric power line group 20c are inserted through the two through holes h of the rubber gasket 23c, respectively, thereby being integrated with the rubber gasket 23c. As a result, the two harnesses 21 of the electric power line group 20c are easily handled, and the two harnesses 21 of the electric power line group 20c are prevented from being improperly connected to the two bus bars BB.

(3-d) The Two-Wheeled Electric Vehicle

The electric power is supplied from the battery system 632 to the power converter 100 in the two-wheeled electric vehicle 600 of FIG. 1. The electric power converted in the power converter 100 is applied to the motor 660, thereby causing the motor 660 to rotate. The torque generated by the motor 660 causes the rear wheel 692 to rotate, so that the two-wheeled electric vehicle moves.

The power converter 100 is constituted by the circuit module shown in FIGS. 3 to 6. Therefore, waterproofness of the power converter 100 is ensured by the main body casing 10C that is molded of resin even when the two-wheeled electric vehicle 600 is used in wet weather or on a flooded road. The respective connections between the bus bars BB of the power converter 100 and the motor power line group 20a and between the bus bars BB of the power converter 100 and the electric power line group 20c are closed by the terminal holder 11, the terminal covers 12a, 12c and the rubber gaskets 23a, 23c. This ensures waterproofness of the respective connections between the bus bars BB and the motor power line group 20a and between the bus bars BB and the electric power line group 20c. In this case, the harnesses 21 of the motor power line group 20a and the electric power line group 20c are removed from the bus bars BB, so that the motor power line group 20a and the electric power line group 20c can be easily removed from the power converter 100 without disassembling the main body casing 10C. As a result, the respective connections between the power converter 100 and the motor power line group 20a and between the power converter 100 and the electric power line group 20c can be reliably waterproofed, and the motor power line group 20a and the electric power line group 20c can be easily replaced.

(4) Other Examples of the Terminal Holder, the Rubber Gasket and the Terminal Cover

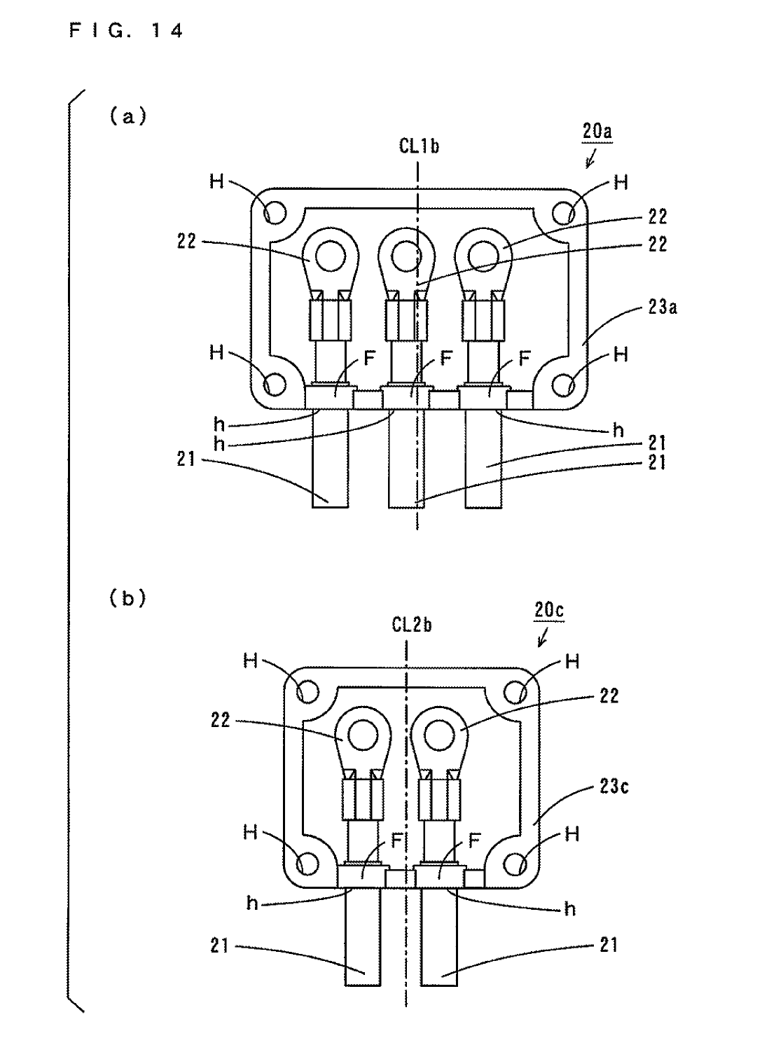

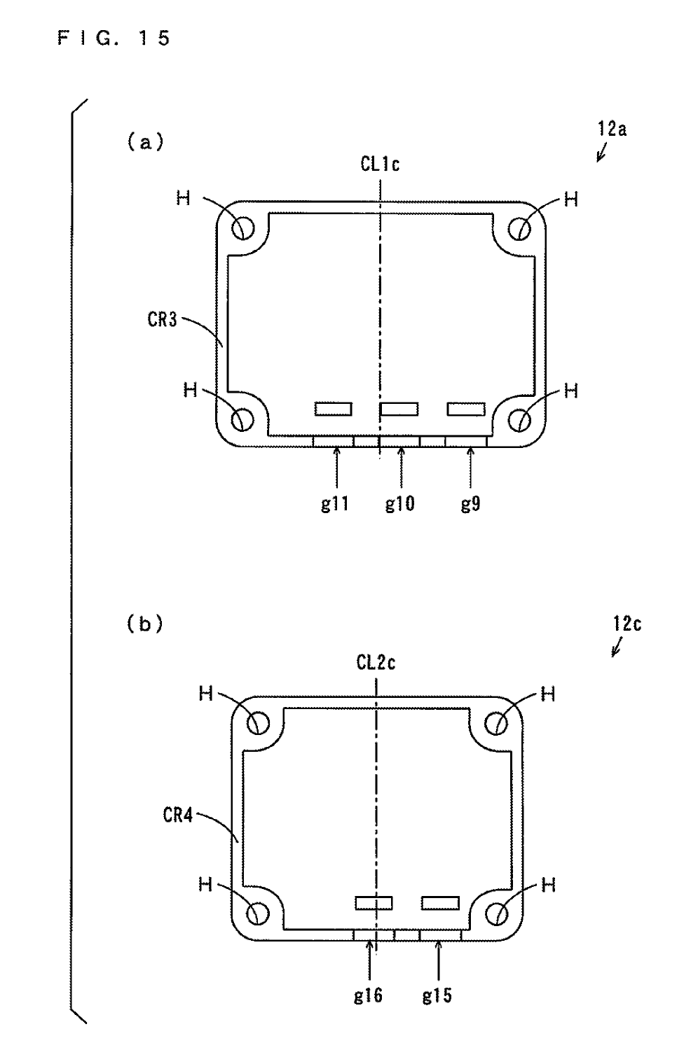

FIG. 13 is a plan view showing another example of the terminal holder 11. FIG. 14 is a plan view showing another example of the rubber gaskets 23a, 23c. FIG. 15 is a plan view showing another example of the terminal covers 12a, 12c.

In the example of FIG. 13, the concave grooves g1, g2 g3 of the terminal holder 11 are asymmetrically arranged with respect to the center line CL1a of the internal region IR1.

Similarly, the concave grooves g7, g8 of the terminal holder 11 are asymmetrically arranged with respect to the center line CL2a of the internal region 1R2.

In the example of FIG. 14 (a), the through holes h and the attachment portions F at the one side of the rubber gasket 23a are asymmetrically arranged with respect to the center line CL1b of the rubber gasket 23a.

In the example of FIG. 14 (b), the through holes h and the attachment portions F at the one side of the rubber gasket 23c are asymmetrically arranged with respect to the center line CL2b of the rubber gasket 23c.

In the example of FIG. 15 (a), the concave grooves g9, g10, g11 are asymmetrically arranged with respect to the center line CL1c of the joint region CR3.

In the example of FIG. 15 (b), the concave grooves g15, g16 are asymmetrically arranged with respect to the center line CL2c of the joint region CR4.

In this case, the rubber gasket 23a, in which the three harnesses 21 constituting the motor power line group 20a are inserted, is prevented from being arranged between the joint region CR1 of the terminal holder 11 and the joint region CR3 of the terminal cover 12a with one surface and the other surface of the rubber gasket 23a arranged in the opposite manner.

This prevents the two harnesses 21 to be fitted in the concave grooves g1, g3, respectively, from being erroneously fitted in the concave grooves g3, g1, respectively. As a result, improper connection between the motor power line group 20a and the circuit board 30 is inhibited.

Similarly, the rubber gasket 23c, in which the two harnesses 21 constituting the electric power line group 20c are inserted, is prevented from being arranged between the joint region CR2 of the terminal holder 11 and the joint region CR4 of the terminal cover 12c with one surface and the other surface of the rubber gasket 23c arranged in the opposite manner.

This prevents the two harnesses 21 to be fitted in the concave grooves g7 g8, respectively, from being erroneously fitted in the concave grooves g8, g7, respectively. As a result, improper connection between the electric power line group 20c and the circuit board 30 is inhibited.

(5) Still Other Examples of the Terminal Holder and the Rubber Gasket

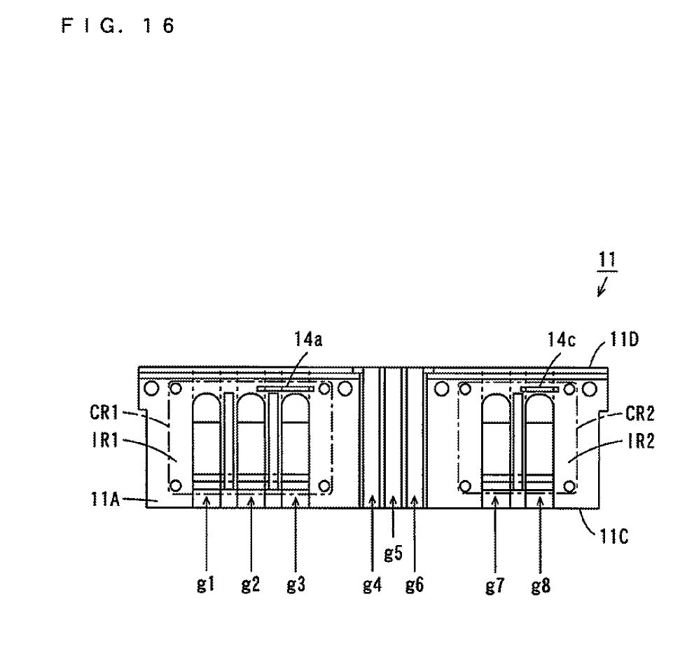

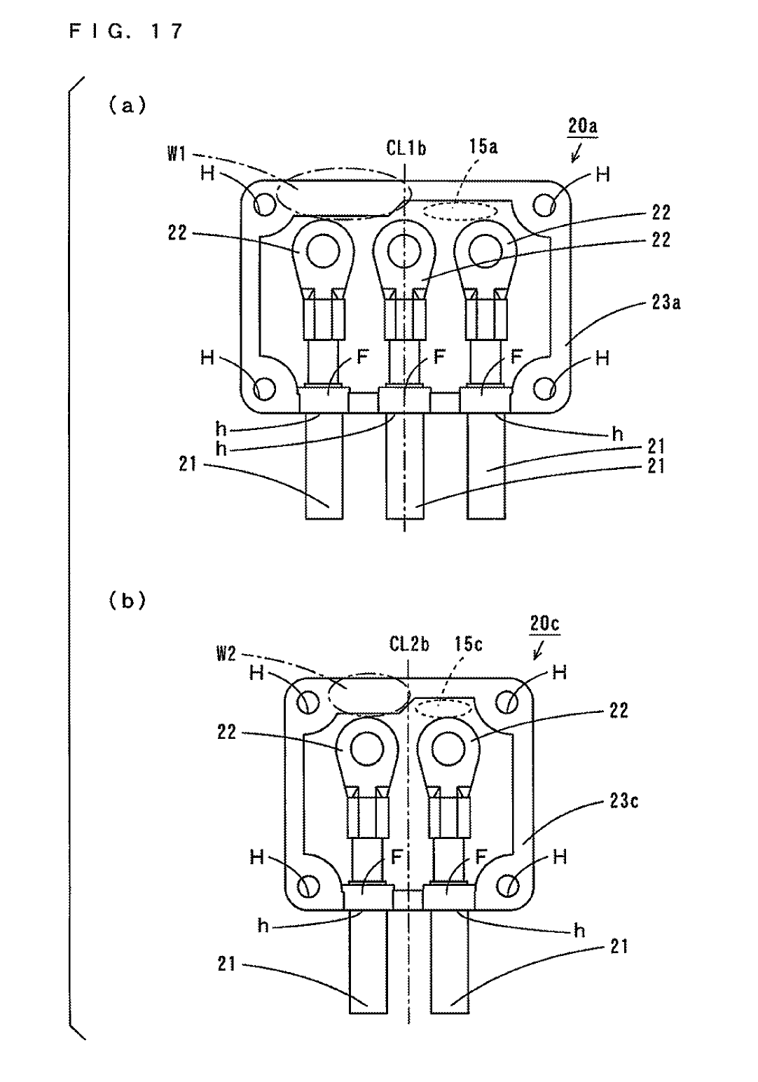

FIG. 16 is a plan view showing still another example of the terminal holder 11. FIG. 17 is a plan view showing still another example of the rubber gaskets 23a, 23c.

In the example of FIG. 16, a projection 14a is formed between the other end surface 11D of the terminal holder 11 and the other end of the concave groove g3. A projection 14c is formed between the other end surface 110 of the terminal holder 11 and the other end of the concave groove g8.

In the example of FIG. 17 (a), a wide portion W1 having a larger width than the other portion is formed in part of the other side of the rubber gasket 23a that is opposite to the one side at which the through holes h are formed. The wide portion W1 is positioned on the opposite side to the projection 14a of the terminal holder 11 of FIG. 16 with respect to the center line Cub. This causes a concave portion 15a to be formed in a position corresponding to the projection 14a of the terminal holder 11.

In the example of FIG. 17 (b), a wide portion W2 having a larger width than the other portion is formed in part of the other side of the rubber gasket 23c that is opposite to the one side at which the through holes h are formed. The wide portion W2 is positioned on the opposite side to the projection 14c of the terminal holder 11 of FIG. 16 with respect to the center line CL2b. This causes a concave portion 15c to be formed in a position corresponding to the projection 14c of the terminal holder 11.

When the one surface of the rubber gasket 23a in which the three harnesses 21 constituting the motor power line group 20a are inserted is arranged on the joint region CR1 of the terminal holder 11, the projection 14a of the terminal holder 11 is fitted in the concave portion 15a of the motor power line group 20a.

In this manner, the rubber gasket 23a, in which the three harnesses 21 constituting the motor power line group 20a are inserted, is prevented from being arranged between the joint region CR1 of the terminal holder 11 and the joint region CR3 of the terminal cover 12a with the one surface and the other surface of the rubber gasket 23a arranged in the opposite manner.

This prevents the two harnesses 21 to be fitted in the concave grooves g1, g3, respectively, from being erroneously fitted in the concave grooves g3, g1, respectively. As a result, improper connection between the motor power line group 20a and the circuit board 30 is inhibited.

Similarly, when the one surface of the rubber gasket 23c in which the two harnesses 21 constituting the electric power line group 20c are inserted is arranged on the joint region CR2 of the terminal holder 11, the projection 14c of the terminal holder 11 is fitted in the concave portion 15c of the electric power line group 20c.

In this manner, the rubber gasket 230, in which the two harnesses 21 constituting the electric power line group 20c are inserted, is prevented from being arranged between the joint region CR2 of the terminal holder 11 and the joint region CR4 of the terminal cover 12c with the one surface and the other surface of the rubber gasket 23c arranged in the opposite manner.

This prevents the two harnesses 21 to be fitted in the concave grooves g7 g8, respectively, from being erroneously fitted in the concave grooves g8, g7, respectively. As a result, improper connection between the rubber gasket 23c and the circuit board 30 is inhibited.

(6) Another Example of the Wire Connector

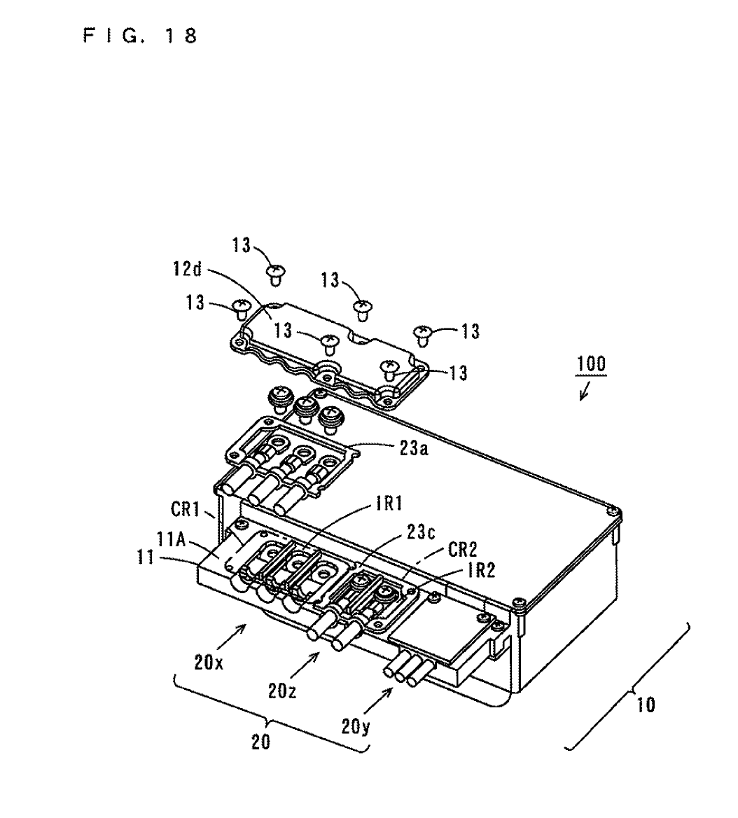

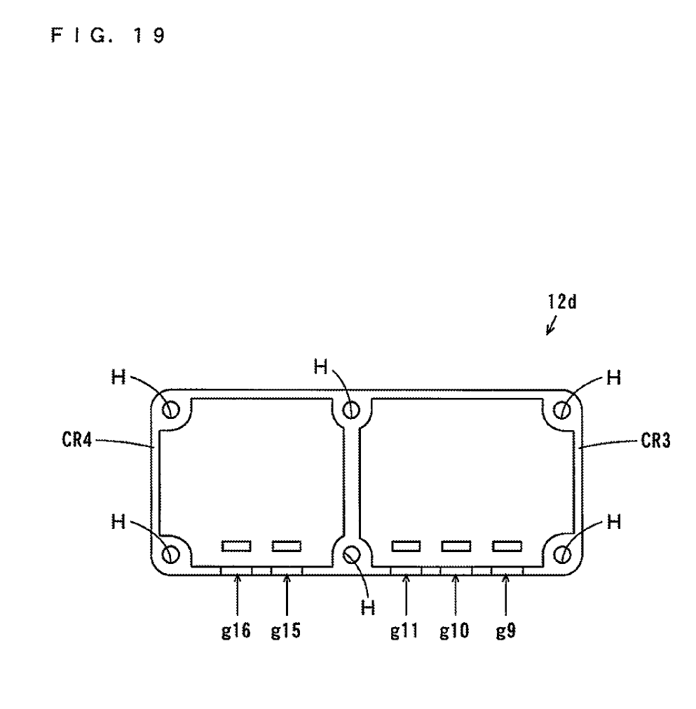

FIG. 18 is an exploded perspective view showing another example of the wire connector 20, and FIG. 19 is a bottom view of a terminal cover 12d in the wire connector 20 of FIG. 18.

In the example of FIG. 18, the first connector portion 20x, the third connector portion 20z and the second connector portion 20y are arranged to line up in this order. Therefore, the first connector portion 20x and the third connector portion 20z having the waterproof construction are adjacent to each other. Thus, the joint region CR1 and the joint region CR2 are arranged adjacent to each other. In this example, the common terminal cover 12d made of resin is used instead of the terminal covers 12a, 12c of FIGS. 10 and 11.

As shown in FIG. 19, the joint regions CR3, CR4 corresponding to the joint regions CR1, CR2 of the terminal holder 11, respectively, are formed on a lower surface of the terminal cover 12d. One side of the joint region CR3 and one side of the joint region CR4 are integrated and used in common.

Each of the joint regions CR3, CR4 projects downward as compared with the region inside thereof. The three concave grooves g9, g10, g11 each having the semicircular shape corresponding to the attachment portion F of the rubber gasket 23a are formed at the one side of the joint region CR3. The two concave grooves g15, g16 each having a semicircular shape corresponding to the attachment portion F of the rubber gasket 23c are formed at the one side of the joint region CR4. Screw holes H are formed in a peripheral portion of the terminal cover 12d.

The joint regions CR3, CR4 of the terminal cover 12d are arranged on the rubber gaskets 23a, 23c, respectively, and the concave grooves g9, g10, g11, g15, g16 are positioned on the five attachment portions F of the rubber gaskets 23a, 23c, respectively. In this state, the terminal cover 12d is attached to the upper surface 11A of the terminal holder 11 by screws 13 with the rubber gaskets 23a, 23c sandwiched therebetween.

In this manner, the common terminal cover 12d is used for the first connector portion 20x and the third connector portion 20z in this example. Accordingly, the plurality of wires (the motor power line group 20a and the electric power line group 20c in this example) can be reliably attached and removed in the smaller number of operation steps as compared with the case where the terminal cover is attached to each of the first connector portion 20x and the third connector portion 20z.

(7) Still Another Example of the Wire Connector

Since the signal line group 20b is less frequently replaced, the signal line group 20b, unlike the motor power line group 20a and the electric power line group 20c, is waterproofed by resin molding inside the main body casing 10C in the circuit module and the electric vehicle including the same according to the above-described embodiment. However, the present invention is not limited to this. The signal line group 20b may be waterproofed by a terminal holder and a terminal cover outside the main body casing 10C, similarly to the motor power line group 20a and the electric power line group 20c.

While the joint regions CR3, CR4 of the terminal covers 12a, 12c, 12d are joined to the joint regions CR1, CR2 of the terminal holder 11 through the rubber gaskets 23a, 23c in the foregoing embodiment, the present invention is not limited to this. The joint regions CR1, CR2 of the terminal holder 11 and the joint regions CR3, CR4 of the terminal covers 12a, 12c, 12d may be directly joined to each other, respectively, not through the rubber gaskets 23a, 23c if airtightness between the terminal holder 11 and the terminal covers 12a, 12c, 12d is maintained.

### [2] Second Embodiment

Description will be made of a circuit module according to a second embodiment while referring to differences from the circuit module according to the first embodiment.

(1) Configuration of the Power Converter

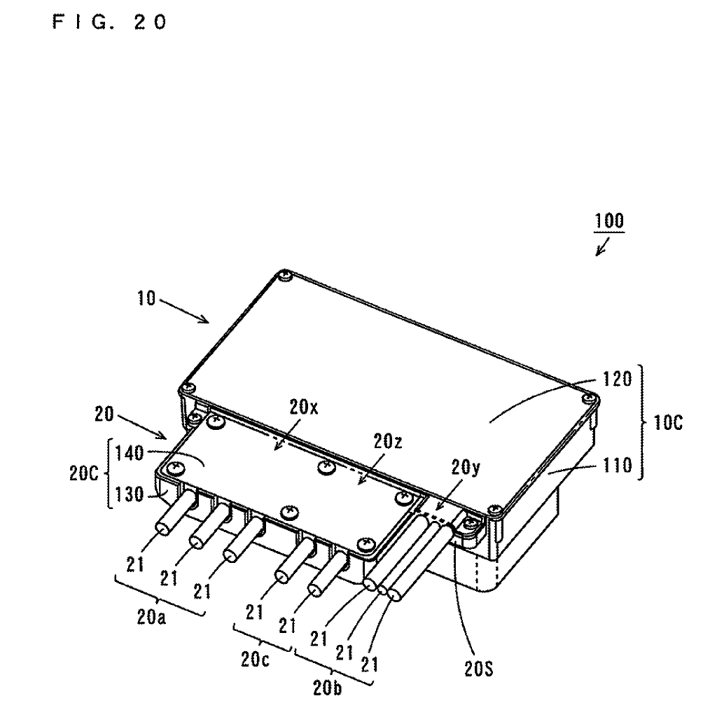

FIG. 20 is an external perspective view of the power converter 100 constituted by the circuit module according to the second embodiment of the present invention. As shown in FIG. 20, the power converter 100 is constituted by the converter main body 10 and the wire connector 20.

Similarly to the first embodiment, the main body casing 10C of the converter main body 10 is composed of the lower casing 110 having the upper opening, and the top cover 120 that closes the upper opening of the lower casing 110. The lower casing 110 has the four side surfaces and the bottom surface. The wire connector 20 is integrally formed in the lower casing 110 so as to extend sideward from one side surface.

The wire connector 20 is composed of a lower casing 130 having the upper opening, and a top cover 140 that closes the upper opening of the lower casing 130. The lower casing 130 has three side surfaces and a bottom surface. A connection casing 20C and a signal line connecter portion 20S are integrally formed to line up on the one side surface of the lower casing 110 of the converter main body 10. The main body casing 10C, the connection casing 20C excluding the top cover 140, and the signal line connector portion 20S are formed of electrically conductive materials such as aluminum. The top cover 140 is formed of an electrically conductive material such as stainless steel.

The first connector portion 20x, the third connector portion 20z and the second connector portion 20y are arranged to line up in this order in the present embodiment. One ends of the motor power line group 20a, the signal line group 20b and the electric power line group 20c are connected to the first connector portion 20x, the second connector portion 20y and the third connector portion 20z, respectively. The first connector portion 20x and the third connector portion 20z have waterproof construction. The motor power line group 20a and the signal tine group 20b are each constituted by the three harnesses 21, and the electric power line group 20c is constituted by the two harnesses 21.

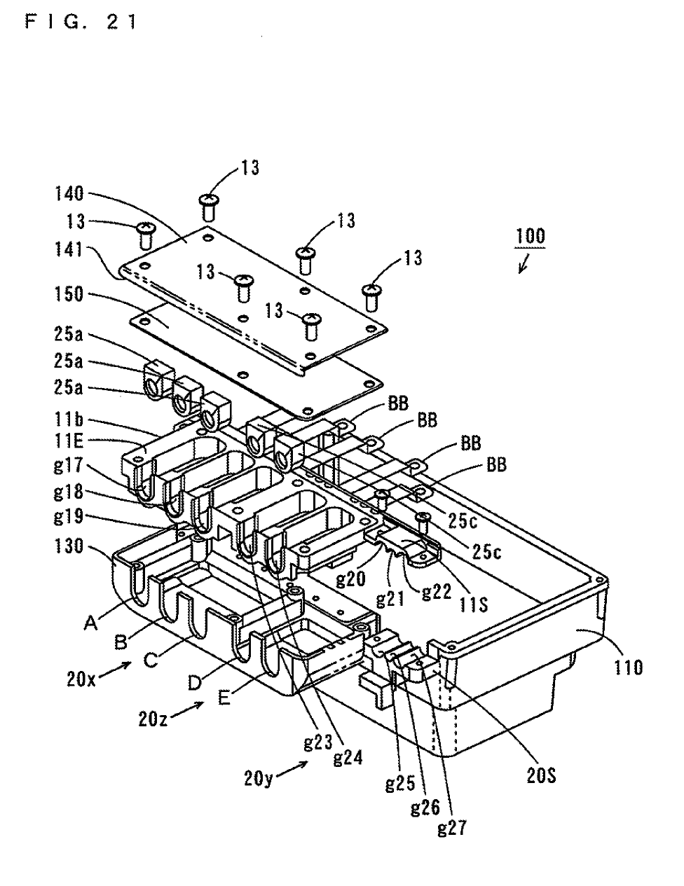

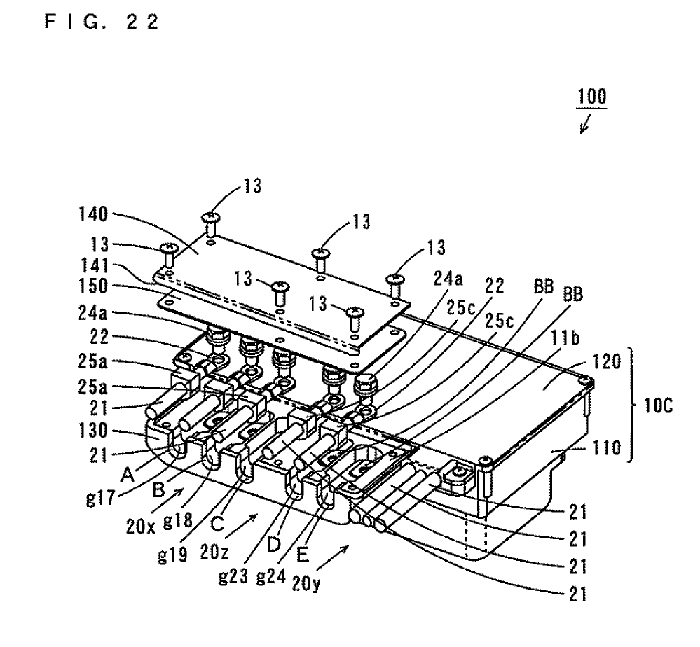

FIGS. 21 and 22 are exploded perspective views of the power converter 100 of FIG. 20. As shown in FIGS. 21 and 22, the first connector portion 20x and the third connector portion 20z of the wire connector 20 are constituted by the connection casing 20C (the lower casing 130 and the top cover 140), a terminal holder 11b made of resin, a plurality of bushings 25a, 25c and a terminal gasket 150. The second connector portion 20y of the wire connector 20 is constituted by a signal line connector portion 11S and the signal line connector portion 20S of the lower casing 130. The signal line connector portion 11S is integrally formed with the terminal holder 11b. The top cover 120 of the main body casing 10C is not shown in FIG. 21.

Three concave portions A, B, C each having a semicircular shape in cross section and corresponding to the three harnesses 21 of the motor power line group 20a (see FIG. 20) and two concave portions D, E corresponding to the two harnesses 21 of the electric power line 20c (see FIG. 20) are formed on one side surface of the lower casing 130 that is opposite to the one side surface of the lower casing 110. The terminal holder lib is fitted in the lower casing 130.

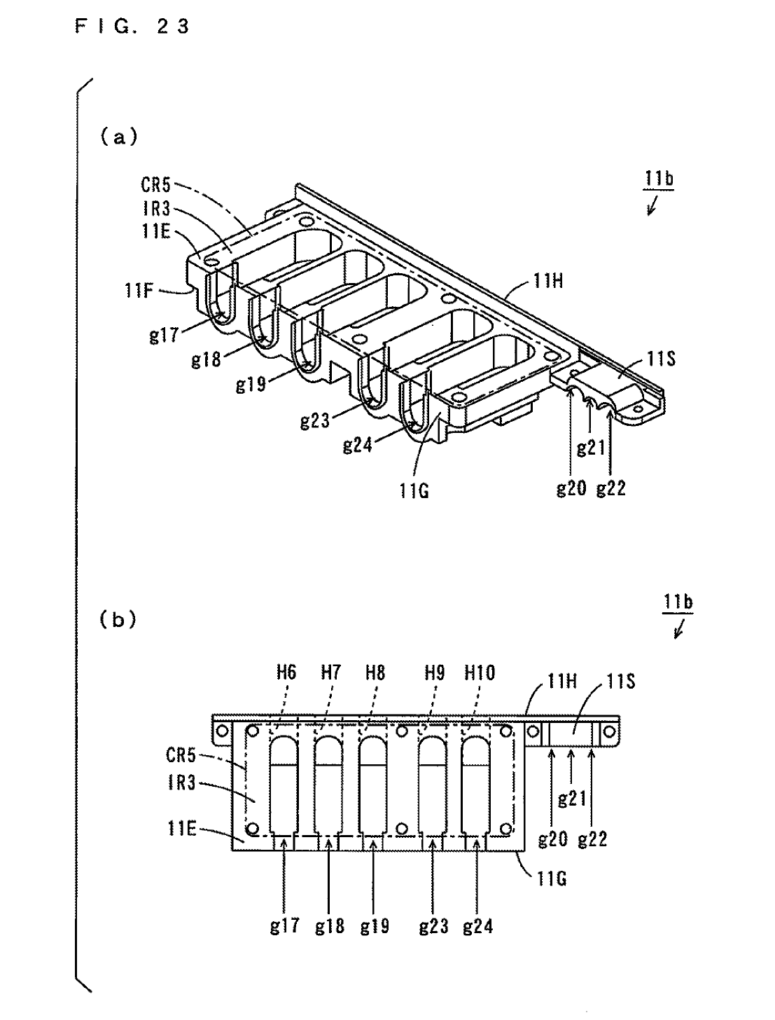

FIG. 23 (a) is a perspective view of the terminal holder 11b of FIG. 21, and FIG. 23 (b) is a plan view of the terminal holder 11b of FIG. 21. As shown in FIG. 23 (a), the terminal holder lib has a flat and rectangular parallelepiped shape, and has an upper surface 11E, a lower surface 11F, one end surface 11G and the other end surface 11H. The signal line connector portion 118 is formed to line up along the other end surface 11H of the terminal holder 11b.

A plurality of concave grooves 917, g18, g19, g23, g24 are formed parallel to one another on the upper surface 11E of the terminal holder 11b to extend from the one end surface 11G to portions near the other end surface 11H. Three concave grooves g20, g21, g22 are formed parallel to one another on a lower surface of the signal line connector portion 11S.

The three concave grooves g17 to g19 correspond to the motor power line group 20a of FIG. 20, and formed within the first connector portion 20x of FIG. 20. The two concave grooves g23, g24 correspond to the electric power line group 20c of FIG. 20, and formed within the third connector portion 20z. The three concave grooves g20 to g22 correspond to the signal line group 20b of FIG. 20, and formed within the second connector portion 20y of FIG. 20. A tip portion of each of the concave grooves g17 to g19, g23, g24 is formed to have a semicircular shape in cross section. Each of the concave grooves g20 to g22 is formed to have a semicircular shape in cross section from its one end surface to its other end surface.

A joint region CR5 is formed on the upper surface 11E to surround the concave grooves g17 to g19, g23, g24 in an integrated manner excluding tip portions of the concave grooves g17 to g19, g23, g24. A region inside the joint region CR5 is referred to as an internal region 1R3.

The terminal holder 11b is fitted in the lower casing 130. In this state, upper surfaces of the concave portions A to E formed on the one side surface of the lower casing 130 are substantially flush with upper surfaces of the tip portions of the concave grooves g17 to g19, g23, g24 formed on the one end surface 11G of the terminal holder 11b (see FIG. 22).

As shown in FIG. 23 (b), a plurality of slits H6, H7, H8, H9, H10 that extend from the other end surface 11H into the concave grooves g17 to g19, g23, g24, respectively, are formed to extend parallel to the lower surface 11F in the terminal holder 11b.

The strip-shaped bus bar BB is inserted in each of the plurality of slits H6 to H10 (see FIG. 21). One ends of the plurality of bus bars BB are exposed inside the concave grooves g17 to g19, g23, g24. Each of the plurality of bus bars BB is formed of copper, for example, and has connection holes at its both ends.

The connection holes at one ends of the plurality of bus bars BB are positioned in the concave grooves g17 to g19, g23, g24 of the terminal holder 11b, and the connection holes at the other ends of the plurality of bus bars BB are positioned on the plurality of terminals 30a to 30e (see FIG. 5) of the circuit board 30. In this state, the other ends of the plurality of bus bars BB are connected to the screw holes of the plurality of terminals 30a to 30e of the circuit board 30 by the screws 31 through the connection holes.

Concave grooves g25, g26, g27 each having a semicircular shape in cross section are formed on an upper surface of the signal line connector portion 20S to be opposite to the three concave grooves g20 to g22 of the signal line connector portion 11S. The three harnesses 21 constituting the signal line group 20b are fitted in the three concave grooves g25 to g27 of the signal line connector portion 205, respectively, and ends of the three harnesses 21 are electrically connected to the circuit board 30 (see FIG. 5).

After that, the three harnesses 21 constituting the signal line group 20b are fitted in the three concave grooves g20 to g22 of the signal line connector portion 11S. In this state, the internal space of the lower casing 110 is filled with resin, and the top cover 120 is attached to the lower casing 110.

Each of the plurality of bushings 25a has a substantially rectangular parallelepiped shape, and is formed of rubber. The bushings 25a each have a lower portion in a semicircular shape in cross section, and can be fitted in the tip portions of the concave grooves g17 to g19 formed in the one end surface 11G of the terminal holder 11b. The bushings 25a each have a flat upper surface.

A through hole is formed in each bushing 25a, and the harness 21 of the motor power line group 20a is inserted through the through hole. The inner diameter of the through hole is substantially equal to the diameter of the harness 21 of the motor power line group 20a. The harnesses 21 constituting the motor power line group 20a of FIG. 20 each have the same configuration as the harness 21 of FIG. 8. After each harness 21 is inserted through the through hole of the bushing 25a, the solderless terminal 22 is attached to the core 21a (see FIG. 8) exposed at the tip portion as shown in FIG. 22.

The bushings 25a are fitted in the tip portions of the concave grooves g17 to g19 while the harnesses 21 of the motor power line group 20a are inserted through the bushings 25a. Thus, the tip portions of the concave grooves g17 to g19 of the terminal holder 11b and the lower surfaces of the bushings 25a adhere to each other, respectively, while being waterproofed. The upper surfaces of the bushings 25a are substantially flush with the upper surface 11E of the terminal holder 11b (see FIG. 23). In this state, the solderless terminals 22 attached to the harnesses 21 are connected to the bus bars BB exposed in the three concave grooves g17 to g19 by the screws 24a as shown in FIG. 22.

Similarly, each of the plurality of bushings 25c has a substantially rectangular parallelepiped shape, and is formed of rubber. The bushings 25c each have a lower portion in a semicircular shape in cross section, and can be fitted in the tip portions of the concave grooves g23, g24 formed in the one end surface 110 of the terminal holder 11b. The bushings 25c each have a flat upper surface.

A through hole is formed in each bushing 25c, and the harness 21 of the electric power line group 20c is inserted through the through hole. The inner diameter of the through hole is substantially equal to the diameter of the harness 21 of the electric power line group 20c. The harnesses 21 constituting the electric power line group 200 of FIG. 20 each have the same configuration as the harness 21 of FIG. 9. After each harness 21 is inserted through the through hole of the bushing 25c, the solderless terminal 22 is attached to the core 21a (see FIG. 9) exposed at the tip portion as shown in FIG. 22.

The bushings 25c are fitted in the tip portions of the concave grooves g23, g24 while the harnesses 21 of the electric power line group 20c are inserted through the bushings 25c. Thus, the tip portions of the concave grooves g23, g24 of the terminal holder 11b and the lower surfaces of the bushings 25c adhere to each other, respectively, while being waterproofed. The upper surfaces of the bushings 25c are substantially flush with the upper surface 11E of the terminal holder 11b (see FIG. 23). In this state, the solderless terminals 22 attached to the harnesses 21 are connected to the bus bars BB exposed in the two concave grooves g23, g24 by the screws 24a as shown in FIG. 22.

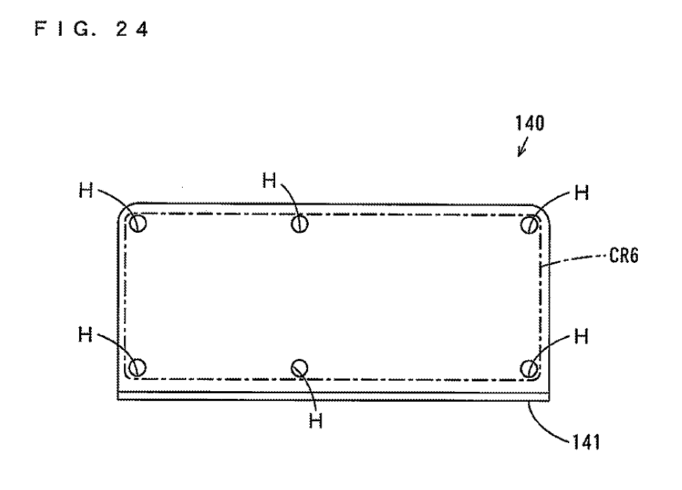

Then, the terminal gasket 150 made of rubber is mounted on the joint region CR5 (see FIG. 23 (a)) of the upper surface 11E of the terminal holder 11b. As shown in FIG. 24, a joint region CR6 is formed at a peripheral edge portion on a lower surface of the top cover 140. The joint region CR6 has a rectangular shape that corresponds to the joint region CR5 of the upper surface 11E of the terminal holder 11b. Screw holes H are formed at a peripheral portion of the top cover 140.

The joint region CR6 of the top cover 140 is arranged on the joint region CR5 of the upper surface 11E of the terminal holder lib with the terminal gasket 150 sandwiched therebetween. In this state, the top cover 140 is attached to the lower casing 130 by the screws 13 (see FIG. 22) with the terminal gasket 150, the bushings 25a, 25c and the terminal holder 11b sandwiched therebetween. Here, the upper surface 11E of the terminal holder lib and the upper surfaces of the bushings 25a, 25c adhere to the lower surface of the terminal gasket 150 while being waterproofed. Accordingly, the terminal holder 11b and the top cover 140 form a closed space above the internal region IR3 of the terminal holder 11b.

As shown in FIG. 21, one end 141 of the top cover 140 corresponding to the one end surface 11G of the terminal holder 11b is bent downward in the present embodiment. This prevents the one end 141 of the top cover 140 from being deflected when the top cover 140 is attached to the lower casing 130 by the screws 13.

The thickness of the top cover 140 may be increased in order to prevent the top cover 140 from being deflected. In this case, the one end 141 of the top cover 140 may not be bent.

In the first connector portion 20x, the solderless terminals 22 attached to the harnesses 21 constituting the motor power line group 20a are connected to the bus bars BB within the closed space above the internal region IR3 of the terminal holder 11b. Accordingly, the three harnesses 21 of the motor power line group 20a are electrically connected to the three terminals 30a, 30b, 30c (see FIG. 5) of the circuit board 30, respectively, through the bus bars BB.

Also in the third connector portion 20z, the solderless terminals 22 attached to the harnesses 21 constituting the electric power line group 20c are connected to the bus bars BB within the closed space above the internal region IR3 of the terminal holder 11b. Accordingly, the two harnesses 21 of the electric power line group 20c are electrically connected to the two terminals 30d, 30e (see FIG. 5) of the circuit board 30, respectively, through the bus bars BB.

(2) Effects

In the present embodiment, the plurality of bushings 25a are fitted in the plurality of concave grooves g17 to g19, which cause the internal region IR3 of the terminal holder 11b and the external space to communicate with each other. The plurality of harnesses 21 constituting the motor power line group 20a are inserted through the through holes of the plurality of bushings 25a, respectively, and connected to the bus bars BB in the internal region IR3 of the terminal holder 11b.

Similarly, the plurality of bushings 25c are fitted in the plurality of concave grooves g23, g24, which cause the internal region IR3 of the terminal holder 11b and the external space to communicate with each other. The plurality of harnesses 21 constituting the electric power line group 20c are inserted through the through holes of the plurality of bushings 25c, respectively, and connected to the bus bars BB in the internal region IR3 of the terminal holder 11b.

In this state, the joint region CR6 of the top cover 140 is joined to the joint region CR5 of the terminal holder 11b with the terminal gasket 150 sandwiched therebetween. Accordingly, spaces between the plurality of concave grooves g17 to g19, g23, g24 of the terminal holder 11b and the plurality of bushings 25a, 25c are sealed, and a space between the joint region CR5 of the terminal holder 11b and the joint region CR6 of the top cover 140 is sealed. Thus, the internal region IR3 including the connections between the bus bars BB and the harnesses 21 is closed by the terminal holder 11b, the top cover 140, the terminal gasket 150 and the bushings 25a, 25c. This results in improved waterproofness of the connections between the bus bars BB and the harnesses 21.

The plurality of bushings 25a and the plurality of concave grooves g17 to g19 are provided corresponding to the plurality of harnesses 21 constituting the motor power line group 20a. Similarly, the plurality of bushings 25c and the plurality of concave grooves g23, g24 are provided corresponding to the plurality of harnesses 21 constituting the electric power line group 20c. This allows the harnesses 21 to be separately removed from the bus bars BB. As a result, replacement operation of the harnesses 21 can be efficiently performed.

The circuit board 30 is accommodated in the main body casing 10C having electrical conductivity, and the one ends of the bus bars BB are accommodated in the connection casing 20C having electrical conductivity. This causes the circuit board 30 and the bus bars BB to be shielded. As a result, entry of noise from the external space into the circuit board 30 and the bus bars BB can be suppressed, and emission of noise from the circuit board 30 and the bus bars BB to the external space can be suppressed.

(3) Another example of the Top Cover of the Connection Casing

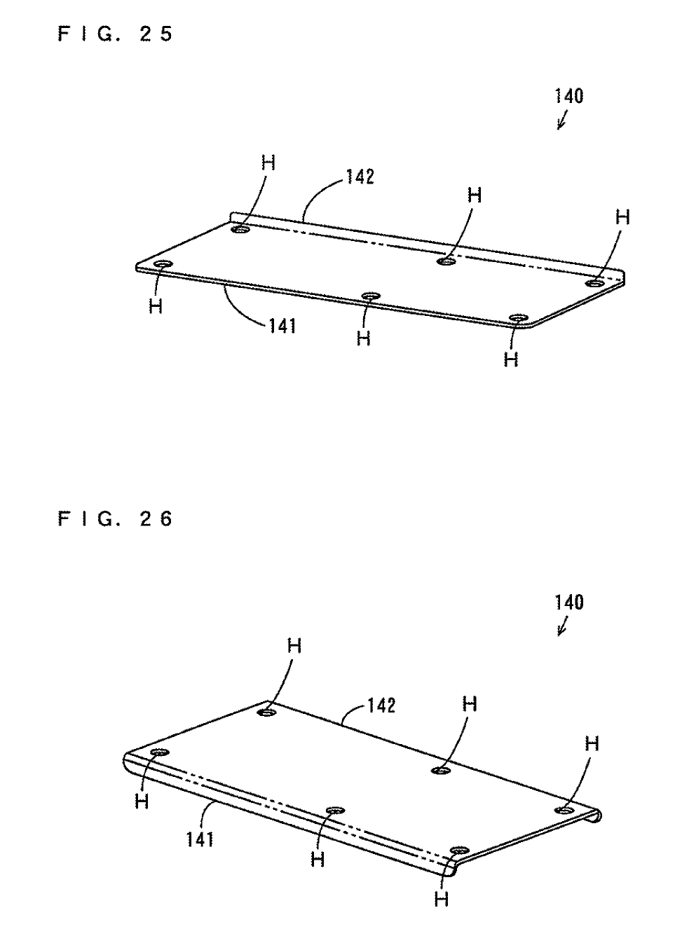

FIG. 25 is a perspective view showing another example of the top cover 140 of the connection casing 20C. In the example of FIG. 25, the one end 141 of the top cover 140 corresponding to the one end surface 11G of the terminal holder 11b of FIG. 23 (b) is not bent, and the other end 142 of the top cover 140 corresponding to the other end surface 11H of the terminal holder 11b is bent upward. This prevents the other end 142 of the top cover 140 from being deflected when the top cover 140 is attached to the lower casing 130 by the screws 13.

The other end 142 of the top cover 140 may be bent downward. Also in this case, the other end 142 of the top cover 140 is prevented from being deflected when the top cover 140 is attached to the lower casing 130 by the screws 13.

(4) Still Another Example of the Top Cover of the Connection Casing

FIG. 26 is a perspective view showing still another example of the top cover 140 of the connection casing 20C. Similarly to the example of FIG. 21, the one end 141 of the top cover 140 corresponding to the one end surface 11G of the terminal holder 11b of FIG. 23 (b) is bent downward in the example of FIG. 26. In addition, the other end 142 of the top cover 140 corresponding to the other end surface 11H of the terminal holder lib is bent downward. This prevents the one end 141 and the other end 142 of the top cover 140 from being deflected when the top cover 140 is attached to the lower casing 130 by the screws 13.

(5) While the solderless terminal 22 is attached to the core 21a of each harness 21 that is exposed at the tip portion after the harnesses 21 constituting the motor power line group 20a and the harnesses 21 constituting the electric power line group 20c are inserted through the through holes of the bushings 25a, 25c, respectively, in the present embodiment, the present invention is not limited to this. The harnesses 21 constituting the motor power line group 20a and the harnesses 21 constituting the electric power line group 20c may be inserted through the through holes of the bushings 25a, 25c, respectively, after the solderless terminal 22 is attached to the core 21a of each harness 21.

Similarly, in the first embodiment, the solderless terminal 22 may be attached to the core 21a of each harness 21 exposed at the tip portion after the harnesses 21 constituting the motor power line group 20a and the harnesses 21 constituting the electric power line group 20c are inserted through the through holes h of the rubber gaskets 23a, 23c, respectively, and the harnesses 21 constituting the motor power line group 20a and the harnesses 21 constituting the electric power line group 20c may be inserted through the through holes h of the rubber gaskets 23a, 23e, respectively, after the solderless terminal 22 is attached to the core 21a of each harness 21.

### [3] Correspondences between Elements in the Claims and Parts in Embodiments

In the following paragraph, non-limiting examples of correspondences between various elements recited in the claims below and those described above with respect to various preferred embodiments of the present invention are explained.

In the above-described embodiments, the main body casing 10C is an example of a first casing, the circuit board 30 is an example of an electronic circuit, the bus bar BB is an example of a terminal, the internal regions IR1 to IR3 are examples of an internal region, the joint regions CR1, CR2, CR5 are examples of a first joint region, and the terminal holders 11, 11b are examples of a terminal holder. The through hole h is an example of a hole, the rubber gaskets 23a, 23c and the bushings 25a, 25c are examples of a seal member, the harness 21 is an example of a wire, the joint regions CR3, CR4, CR6 are examples of a second joint region, the terminal covers 12a, 12c or 12d or the top cover 140 is an example of a cover, and the wire connector 20 is an example of a wire connector. The core 21a is an example of a core, the shield line 21c is an example of a shield conductor, the concave grooves g17 to g19, g23, g24 are examples of a groove, and the connection casing 20C is an example of a second casing. The power converter 100 is an example of a power converter, the battery system 632 is an example of a battery system, the motor 660 is an example of a motor, the rear wheel 692 is an example of a drive wheel, and the two-wheeled electric vehicle 600 is an example of an electric vehicle.

As each of various elements recited in the claims, various other elements having configurations or functions described in the claims can be also used.

While preferred embodiments of the present invention have been described above, it is to be understood that variations and modifications will be apparent to those skilled in the art without departing the scope and spirit of the present invention. The scope of the present invention, therefore, is to be determined solely by the following claims.

I/We claim:

1. A circuit module comprising:
a first casing having an internal space;
an electronic circuit accommodated in said internal space of said first casing;
a terminal electrically connected to said electronic circuit and drawn out of said first casing;
a terminal holder provided outside said first casing, having an internal region in which said terminal is held, and having a first joint region that surrounds said internal region;
a wire; and
a cover having a second joint region that corresponds to said first joint region of said terminal holder, and formed to cover said internal region of said terminal holder, wherein
said second joint region of said cover is joined to said first joint region of said terminal holder while one end of said wire is connected to said terminal in said internal region of said terminal holder and the other end of said wire is drawn out to an external space.

2. The circuit module according to claim 1, further comprising a seal member arranged on said first joint region to surround said internal region of said terminal holder, and having a plurality of holes that pass said seal member from said external space to said internal region, wherein
said terminal includes a plurality of terminals, and said wire includes a plurality of wires, said plurality of wires can be inserted through said plurality of holes, respectively, of said seal member, said plurality of terminals are held in said internal region of said terminal holder, said wires inserted through said plurality of holes of said seal member are connected to said plurality of terminals, respectively, in said internal region of said terminal holder, and said second joint region of said cover is joined to said first joint region of said terminal holder through said seal member.

3. The circuit module according to claim 2, wherein
said seal member includes a plurality of seal members, said first joint region includes a plurality of first joint regions, said second joint region includes a plurality of second joint regions, said terminal holder has a plurality of internal regions in which said plurality of terminals are held, and said plurality of first joint regions that surround said plurality of internal regions, respectively, and said cover has said plurality of second joint regions that correspond to said plurality of first joint regions of said terminal holder, and
said plurality of wires inserted through said plurality of holes of said plurality of seal members, respectively, are connected to said plurality of terminals in said plurality of internal regions of said terminal holder, respectively, and said plurality of second joint regions of said cover are joined to said plurality of first joint regions of said terminal holder through said plurality of seal members.

4. The circuit module according to claim 2, wherein
said terminal holder is formed such that said seal member can be fitted in said terminal holder, and
said seal member has a first surface and a second surface, and is shaped so as to be fitted in said terminal holder while said first surface is opposite to said first joint region, and is shaped so as not to be fitted in said terminal holder while said second surface is opposite to said first joint region.

5. The circuit module according to claim 1, wherein
said first casing has electrical conductivity,
said terminal is electrically insulated from said first casing, and
said wire has a core and a shield conductor, said core is connected to said terminal, and said shield conductor is electrically connected to said first casing.

6. The circuit module according to claim 1, wherein
said terminal includes a plurality of terminals, and said wire includes a plurality of wires,
said terminal holder has a plurality of grooves that are provided corresponding to said plurality of wires and cause said internal region and said external space to communicate with each other,
said circuit module further comprises a plurality of seal members that are formed so as to be fitted in said plurality of grooves of said terminal holder, respectively, and each have a hole that passes said seal member from said external space to said internal region, and
said plurality of wires can be inserted through said holes of said plurality of seal members, respectively, said plurality of terminals are held in said internal region of said terminal holder, said plurality of wires inserted through said holes of said plurality of seal members are connected to said plurality of terminals in said internal region of said terminal holder, and said second joint region of said cover is joined to said first joint region of said terminal holder through said plurality of seal members.

7. The circuit module according to claim 6, further comprising a second casing provided outside said first casing, wherein
said terminals, said terminal holder and said cover are accommodated in said second casing, and said plurality of wires are drawn out from said second casing to said external space, and
said first casing and said second casing have electrical conductivity.

8. An electric vehicle comprising;
a power converter composed of the circuit module according to claim 1;
a battery system arranged to supply electric power to said power converter;
a motor driven by said power converter; and
a drive wheel rotated by a torque generated by said motor.
